(19) United States
(12) Patent Application Publication
(10) Pub. No.: US 2024/0357849 A1
(43) Pub. Date: Oct. 24, 2024

(54) FILM PATTERNING METHOD AND ELECTROLUMINESCENT DEVICE AND DISPLAY DEVICE INCLUDING A PATTERNED FILM

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Moon Gyu HAN, Suwon-si (KR); Himchan CHO, Daejeon (KR); Tae Ho KIM, Suwon-si (KR); Seongkyu MAENG, Daejeon (KR); Sun Jae PARK, Daejeon (KR); Shin Ae JUN, Suwon-si (KR)

(21) Appl. No.: 18/637,854

(22) Filed: Apr. 17, 2024

(30) Foreign Application Priority Data
Apr. 19, 2023 (KR) 10-2023-0051499
Jun. 14, 2023 (KR) 10-2023-0076415

(51) Int. Cl. H10K 50/115; G03F 7/027; G03F 7/32; H10K 50/15; H10K 50/16; H10K 85/10

(52) U.S. Cl. CPC H10K 50/115; G03F 7/0275; G03F 7/325; H10K 50/15; H10K 50/16; H10K 85/143

(57) ABSTRACT

A method of manufacturing a patterned film includes forming a first film including a semiconductor nanoparticle and an additive, wherein the additive includes a polythiol compound, the semiconductor nanoparticle includes an organic ligand (for example, on a surface thereof), and the organic ligand includes a first functional group bonded to the surface of the semiconductor nanoparticle and a carbon-carbon unsaturated bond; exposing a portion of the first film to a radiation to cause a change in a solubility of the semiconductor nanoparticle in the exposed area with respect to a first solvent; contacting the radiation treated film with the first solvent to remove at least a portion of an unexposed area of the radiation treated film to obtain a patterned film. A light emitting device includes such a patterned film as a light emitting layer.

### CROSS-REFERENCE TO RELATED APPLICATION

This application claims priority to Applications Nos. 10-2023-0051499 and 10-2023-0076415 filed in the Korean Intellectual Property Office on Apr. 19, 2023 and Jun. 14, 2023 respectively, and all the benefits accruing therefrom under 35 U.S.C. § 119, the contents of both of which are incorporated herein by reference in their entirety.

### BACKGROUND

### 1. Field

The present disclosure relates to a method of patterning a semiconductor nanocrystal film, and an electroluminescent device and a display device including a patterned semiconductor nanocrystal film.

### 2. Description of the Related Art

A semiconductor nanoparticle (e.g., a semiconductor nanocrystal particle) may emit light. For example, a quantum dot including a semiconductor nanocrystal may exhibit a quantum confinement effect, showing, e.g., exhibiting, luminous properties. Light emission of the semiconductor nanoparticle may be generated, for example, as an electron in an excited state, by light excitation or by application of a voltage, moves, e.g., transitions, from a conduction band to a valence band. The semiconductor nanoparticle may be configured to emit light of a desired wavelength region by controlling a size, composition, or a combination thereof of the semiconductor nanoparticle.

The semiconductor nanoparticle may find its application in an electronic or electrooptic device, for example, a display device or a sensor, and for the application, developing a technology for patterning a semiconductor nanoparticle-based film is desired.

### SUMMARY

A method of producing a patterned film including a semiconductor nanoparticle and the patterned film produced therefrom are provided.

An electronic device (e.g., an electroluminescent device) includes the patterned film including the semiconductor nanoparticle.

A display device (e.g., a quantum dot light emitting diode (“QD-LED”) display) includes the patterned film.

A method of producing a patterned film (e.g., a patterned semiconductor nanocrystal film) having a first region configured to emit a first light includes:
forming a first film including a semiconductor nanoparticle and an additive, wherein the additive includes a polythiol compound containing at least two thiol groups and the semiconductor nanoparticle is configured to emit the first light, the semiconductor nanoparticle includes an organic ligand (for example, on a surface thereof), and the organic ligand includes a first functional group bonded to a surface of the semiconductor nanoparticle and a carbon-carbon unsaturated bond;
exposing a portion of the first film corresponding to the first region to a radiation to cause a change in a solubility of the semiconductor nanoparticle in an exposed area with respect to a first solvent to form a radiation treated film;
contacting the radiation treated film with the first solvent to remove at least a portion of an unexposed area of the radiation treated film to obtain a patterned film having the first region.

In the method, the semiconductor nanoparticle may be configured to function (or may act) as a photocatalyst for a reaction between the organic ligand and the polythiol compound.

The polythiol compound may include a dithiol compound, a trithiol compound, a tetrathiol compound, or a combination thereof.

The polythiol compound may have a molecular weight of from about 10 g/mol to about 5,000,000 g/mol, from about 50 g/mol to about 300,000 g/mol, from about 500 g/mol to about 100,000 g/mol, or from about 1000 g/mol to about 50,000 g/mol.

The polythiol compound may include —O—, —CO—, —COO—, —NR—, —CONR— (R in —NR— and —CONR— is independently hydrogen or a C1 to C10 hydrocarbon group), a substituted or unsubstituted C1 to C20 alkylene group, a substituted or unsubstituted C2 to C20 alkenylene group, a substituted or unsubstituted C2 to C20 alkynylene group, or a combination thereof (for example, a moiety formed by linking at least two of the foregoing groups).

The polythiol compound may include a central moiety and at least one (e.g., at least two) HS—R—* (where R is a substituted or unsubstituted C1 to C30 aliphatic hydrocarbon group or a substituted or unsubstituted C1 (or C2) to C30 aliphatic hydrocarbon group having at least one methylene group being replaced with a sulfonyl, carbonyl, ether, sulfide, sulfoxide, ester, amide, or a combination thereof) and the central moiety may include a carbon atom, a substituted or unsubstituted C1 to C30 aliphatic hydrocarbon group, a substituted or unsubstituted C3 to C30 alicyclic hydrocarbon group, a substituted or unsubstituted C6 to C30 aromatic hydrocarbon group, a substituted or unsubstituted C3 to C30 heteroarylene group, a substituted or unsubstituted C3 to C30 heterocyclic group, or a combination thereof.

The polythiol compound may include a dimercaptoacetate compound, a trimercaptoacetate compound, a tetramercaptoacetate compound, a dimercaptopropionate compound, a trimercaptopropionate compound, a tetramercaptopropionate compound, an isocyanate compound including two or more mercaptoalkylcarbonyloxyalkyl groups, an isocyanurate compound including two or more mercaptoalkylcarbonyloxyalkyl groups, or a combination thereof.

The semiconductor nanoparticle may include a Group II-VI compound, a Group III-V compound, a Group IV-VI compound, a Group IV element or a compound thereof, a Group II-III-VI compound, a Group I-III-VI compound, a Group I-II-IV-VI compound, a metal halide perovskite compound, a transition metal chalcogenide perovskite compound, or a combination thereof.

The first light may have a red light spectrum, a green light spectrum, or a blue light spectrum.

A full width at half maximum of the first light may be greater than or equal to about 1 nanometer (nm) and less than or equal to about 70 nm.

The first functional group may include a carboxyl group, a thiol group, an amine group, a phosphine group, a phosphine oxide group, an ester group, a hydroxyl group, or a combination thereof.

The carbon-carbon unsaturated bond may include a carbon-carbon double bond.

The organic ligand may include a C1 to C50 aliphatic group.

In the first film or the patterned film, an amount of the semiconductor nanoparticle may be greater than or equal to about 60 wt % to less than or equal to about 99.99 wt %, or greater than or equal to about 70 wt % to less than or equal to about 95 wt %, based on a total weight of the first film or the patterned film.

An amount of the additive in the first film may be greater than or equal to about 0.01 wt % to less than or equal to about 40 wt %, or greater than or equal to about 5 wt % to less than or equal to about 30 wt %, based on a total weight of the first film.

The first film may further include or may not substantially include a polymerizable monomer. An amount of the polymerizable monomer in the first film may be less than or equal to about 5 wt %, less than or equal to about 3 wt %, or less than or equal to about 1 wt %, based on the total weight of the first film.

The polymerizable monomer may be a (meth)acrylic monomer including two or more carbon-carbon double bonds, a (meth)acrylic oligomer including a carbon-carbon double bond, a vinyl monomer, or a combination thereof.

The first film may include or may not include an organic compound containing two or more azide groups; an organic polymer with an acid value of greater than or equal to about 50 mg KOH per gram of the organic polymer and soluble in an aqueous alkali solution; an organic compound containing an oxetane group and an aromatic hydrocarbon group; or a combination thereof.

The radiation may have an energy greater than a bandgap energy of the semiconductor nanoparticle.

The radiation may be a light with a peak emission wavelength of greater than or equal to about 150 nanometers (nm), greater than or equal to about 200 nm, greater than or equal to about 250 nm, greater than or equal to about 300 nm, greater than or equal to about 400 nm, greater than or equal to about 480 nm, greater than or equal to about 510 nm, or greater than or equal to about 580 nm, to less than or equal to about 600 nm, less than or equal to about 560 nm, less than or equal to about 500 nm, less than or equal to about 450 nm, or less than or equal to about 390 nm.

A radiation dose for the first film may be greater than or equal to about 0.1 millijoules per square centimeter (mJ/cm²), greater than or equal to about 10 mJ/cm² to less than or equal to about 5000 mJ/cm², less than or equal to about 1000 mJ/cm², less than or equal to about 500 mJ/cm², less than or equal to about 400 mJ/cm², or less than or equal to about 50 mJ/cm².

The first solvent may include an organic solvent being capable of (or configured to) dispersing (or disperse) the semiconductor nanoparticle, in particular the semiconductor nanoparticle in the unexposed area of the radiation treated film. The organic solvent may be a polar solvent.

The organic solvent may include or may be a non-polar solvent. A change in a solubility of the semiconductor nanoparticle in the exposed area of the radiation treated film for the first solvent may allow the semiconductor nanoparticle to have a (solubility or dispersibility) resistance to the first solvent.

The patterned film may have a relative light emitting efficiency of greater than or equal to about 70%, greater than or equal to about 75%, greater than or equal to about 80%, greater than or equal to about 90%, greater than or equal to about 100%, greater than or equal to about 103%, greater than or equal to about 106%, greater than or equal to about 108%, greater than or equal to about 110%, or greater than or equal to about 115% and less than or equal to about 200%, less than or equal to about 150%, less than or equal to about 130%, less than or equal to about 120%, less than or equal to about 110%, less than or equal to about 105%, wherein the relative light emitting efficiency is defined below:

$$\\ Relative Light Emitting Efficiency ( \% ) = [ A / B ] \times 100$$

A: a quantum efficiency of the patterned film
B: a quantum efficiency of a film including the same semiconductor nanoparticle as the patterned film without the additive.

A light emitting efficiency of the patterned film may be greater than or equal to a light emitting efficiency of the semiconductor nanoparticle dispersed in a solution.

In an embodiment, an electroluminescent device includes a first electrode and a second electrode, for example facing each other; and a light emitting layer disposed between the first electrode and the second electrode.

The light emitting layer includes a patterned film including a first region configured to emit a first light, the first region includes a semiconductor nanoparticle and a carbon-sulfur bond containing moiety, and the semiconductor nanoparticle is configured to emit the first light and exhibits a dissolution resistance to a (predetermined) first solvent.

The electroluminescent device may further include a hole transport layer placed between the light emitting layer and the first electrode.

The hole transport layer may include a hole transport material and may not include the semiconductor nanoparticle.

The light emitting layer may be prepared in a method described herein.

The electroluminescent device may include a first pixel and a second pixel, and the first region may be disposed to correspond to the first pixel.

The first solvent may include a non-polar solvent.

The first solvent may include toluene, octane, hexane, chlorobenzene, dichlorobenzene, chloroform, xylene, or a combination thereof.

The first solvent may include dimethylformamide, gamma butyrolactone, N-methylpyrrolidone, dimethyl sulfoxide, dichloroethylene, trichloroethylene, chloroform, chlorobenzene, dichlorobenzene, styrene, xylene, toluene, cyclohexene, or a combination thereof.

In the light emitting layer, two or more semiconductor nanoparticles may be connected by a carbon-sulfur bond containing moiety.

In the light emitting layer, a carbon content may be greater than or equal to about 1 wt % to less than or equal to about 50 wt %, greater than or equal to about 10 wt % to less than or equal to about 30 wt %, or greater than or equal to about 15 wt % to less than or equal to about 25 wt %, based on a total weight of the light emitting layer.

The light emitting layer may not include a chemical species formed from a reaction between an azide group and an alkyl group.

The light emitting layer may not include an organic polymer having an acid value of 50 mg KOH per gram of the organic polymer or more and soluble in an aqueous alkali solution.

The electroluminescent device may further include an electron transport layer between the light emitting layer and the second electrode, and the electron transport layer may include zinc oxide nanoparticles.

The semiconductor nanoparticle in the light emitting layer may include a Group II-VI compound, a Group III-V compound, a Group IV-VI compound, a Group IV element or a compound thereof, a Group II-III-VI compound, a Group I-III-VI compound, a Group I-II-IV-VI compound, a metal halide perovskite compound, a transition metal chalcogenide perovskite compound, or a combination thereof.

The first light may have a red light spectrum, a green light spectrum, or a blue light spectrum.

In an embodiment, a display device includes a first pixel and a second pixel, wherein the display device includes the electroluminescent device, and the first region is disposed to correspond to the first pixel of the electroluminescent device.

The display device may include a portable terminal device, a monitor, a laptop, a television, an electronic display, a camera, or electronic components (for example, of an electric vehicle).

According to an embodiment, a patterned film including a semiconductor nanoparticle with improved optical properties (e.g., a light emitting efficiency) can be obtained. The semiconductor nanoparticle-based patterned film can exhibit an improved organic solvent resistance, and it can be advantageously used in various devices involving a complex pattern of semiconductor nanoparticles, for example, a display device, a sensor, etc.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1A is a flowchart of a patterning method according to an embodiment;

FIG. 1B is a view schematically illustrating a method of patterning a semiconductor nanocrystal film according to an embodiment;

FIG. 1C is a view schematically illustrating a patterned film having more than one light emitting regions;

FIG. 2A is a view schematically illustrating a ligand crosslinking via a photocatalytic reaction in a patterning method of an embodiment;

FIG. 2B is a diagram schematically illustrating passivation of a surface of a semiconductor nanocrystal by an additive in a patterning method of an embodiment;

FIG. 2C is a view illustrating an energy scheme for photocatalytication of semiconductor nanoparticles in a patterning method of an embodiment;

FIG. 2D is a view illustrating a reaction scheme between an additive and a ligand in a patterning method of an embodiment;

FIG. 3A is a schematic cross-sectional view of an embodiment of an electroluminescent device;

FIG. 3B is a schematic cross-sectional view of another embodiment of an electroluminescent device;

FIG. 3C is a schematic cross-sectional view of still another embodiment of an electroluminescent device;

FIG. 4A and FIG. 4B are top views of perovskite semiconductor nanocrystal-based patterned films prepared in Example 1;

FIG. 5 is a top view of a cadmium selenide semiconductor nanocrystal-based patterned film prepared in Example 2;

FIG. 6 is a graph of PLQY (percent, %) versus UV dose (Joules per square centimeter, J/cm²), showing the results of Evaluation Example 4 (photo stability experiment);

FIG. 7 is a graph of intensity (arbitrary unit, a.u.) versus Raman shift (reciprocal centimeter, cm 1) showing the results of Raman spectrum analysis in Evaluation Example 1;

FIG. 8 is a graph of intensity (arbitrary unit, a.u.) versus binding energy (electron volt, eV), illustrating an X-ray Photoelectron Spectroscopy (XPS) analysis result in Evaluation Example 1;

FIG. 9 is a graph of photoluminescence (PL) intensity (arbitrary unit, a.u.) versus time (nanosecond, ns), showing the results of Time-Resolved Photoluminescence (TRPL) analysis in Evaluation Example 1; and

FIG. 10 is a view showing a top image of a pattern formed in Example 4.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

As used herein, the wording “cross-sectional view” means a view observed as a cut for a given object has been made (e.g., substantially perpendicular to the bottom surface). As used herein, the wording “top view” means a view obtained as a given object is observed from above (e.g., directly above).

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. In addition, for example, the wording “a nanoparticle” and “the nanoparticle” may refer to a single nanoparticle or a plurality of the nanoparticles. “At least one” is not to be construed as limiting “a” or “an.” “Or” means “and/or.” As used herein, the term “and/or” includes any and all combinations of one or more of the associated listed items.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10%, 5%, 3%, or 1% of the stated value.

Relative terms, such as “downward,” “lower,” or “bottom,” and “upward,” “upper,” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, values of a work function, a conduction band, or a lowest unoccupied molecular orbital (“LUMO”) (or valence band, or highest occupied molecular orbital (“HOMO”)) energy level is expressed as an absolute value from a vacuum level. In addition, when the work function or the energy level is referred to be “deep,” “high” or “large,” the work function or the energy level has a large absolute value based on “0 electron volts (eV)” of the vacuum level, while when the work function or the energy level is referred to be “shallow,” “low,” or “small,” the work function or energy level has a small absolute value based on “0 eV” of the vacuum level. In an aspect, work function herein refers to a minimum energy to remove an electron from e.g., a solid metal (e.g., a metal surface) to vacuum (e.g., immediately outside the solid surface).

As used herein, when a definition is not otherwise provided, “substituted” refers to replacement of hydrogen of a compound, a group, or a moiety by a C1 to C30 alkyl group, a C2 to C30 alkenyl group, a C2 to C30 alkynyl group, a C2 to C30 epoxy group, a C2 to C30 alkyl ester group, a C3 to C30 alkenyl ester group (e.g., an acrylate group, methacrylate group), a C6 to C30 aryl group, a C7 to C30 alkylaryl group, a C1 to C30 alkoxy group, a C1 to C30 heteroalkyl group, a C3 to C40 heteroaryl group, a C3 to C30 heteroarylalkyl group, a C3 to C30 heteroalkylaryl group, a C3 to C30 cycloalkyl group, a C3 to C15 cycloalkenyl group, a C6 to C30 cycloalkynyl group, a C2 to C30 heterocycloalkyl group, a halogen (—F, —Cl, —Br, or —I), a hydroxy group (—OH), a nitro group (—NO₂), a thiocyanate group (—SCN), a cyano group (—CN), an amino group (—NRR′ wherein R and R′ are independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O) H), a carbamoyl group (—C(O)NH₂), a thiol group (—SH), an ester group (—C(═O)OR, wherein R is a C1 to C6 alkyl group or a C6 to C12 aryl group), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, when a definition is not otherwise provided, “hydrocarbon” or “hydrocarbon group” refers to a compound or a group including carbon and hydrogen (e.g., alkyl, alkenyl, alkynyl, or aryl group). The hydrocarbon group may be a monovalent group or a group having a valence of greater than one formed by removal of one or more hydrogen atoms from an alkane, an alkene, an alkyne, or an arene. In the hydrocarbon or hydrocarbon group, a, e.g., at least one, methylene may be replaced by an oxide moiety, a carbonyl moiety, an ester moiety, —NH—, or a combination thereof. Unless otherwise stated to the contrary, the hydrocarbon or the hydrocarbon group (alkyl, alkenyl, alkynyl, or aryl) may have 1 to 60, 2 to 32, 3 to 24, or 4 to 12 carbon atoms.

As used herein, when a definition is not otherwise provided, “alkyl” refers to a linear or branched saturated monovalent hydrocarbon group (methyl, ethyl, hexyl, etc.). In an embodiment, an alkyl group may have from 1 to 50 carbon atoms, or 2 to 18 carbon atoms, or 3 to 12 carbon atoms.

As used herein, when a definition is not otherwise provided, “alkylene” refers to a linear or branched saturated polyvalent (e.g., divalent) hydrocarbon group (methylene, ethylene, hexylene, etc.). An alkylene group may have from 1 to 50 carbon atoms, or 2 to 18 carbon atoms, or 3 to 12 carbon atoms.

As used herein, when a definition is not otherwise provided, “alkenyl” refers to a linear or branched monovalent hydrocarbon group having a carbon-carbon double bond. In an embodiment, an alkenyl group may have from 2 to 50 carbon atoms, or 3 to 18 carbon atoms, or 4 to 12 carbon atoms.

As used herein, when a definition is not otherwise provided, “alkenylene” refers to a linear or branched polyvalent (e.g., divalent) hydrocarbon group having a carbon-carbon double bond. An alkenylene group may have from 2 to 50 carbon atoms, or 3 to 18 carbon atoms, or 4 to 12 carbon atoms.

As used herein, when a definition is not otherwise provided, “alkynyl” refers to a linear or branched monovalent hydrocarbon group having a carbon-carbon triple bond. In an embodiment, an alkynyl group may have from 2 to 50 carbon atoms, or 2 to 18 carbon atoms, or 2 to 12 carbon atoms.

As used herein, when a definition is not otherwise provided, “alkynylene” refers to a linear or branched polyvalent (e.g., divalent) hydrocarbon group having a carbon-carbon triple bond. An alkynylene group may have from 2 to 50 carbon atoms, or 2 to 18 carbon atoms, or 2 to 12 carbon atoms.

As used herein, when a definition is not otherwise provided, the “aryl” and “arylene” refer to a monovalent and polyvalent (e.g., divalent) group having a carbocyclic aromatic system, respectively. When the aryl group or arylene includes a plurality of rings, the plurality of rings may be fused to each other. Examples of the aryl include a phenyl group and a naphthyl group. Examples of the arylene include a phenylene group, a biphenylene group, and a naphthylene group. In an embodiment, an aryl or arylene group may have 6 to 50 carbon atoms, or 6 to 18 carbon atoms, or 6 to 12 carbon atoms.

As used herein, when a definition is not otherwise provided, “hetero” refers to inclusion of 1 to 3 heteroatoms, e.g., N, O, P, Si, B, Se, Ge, Te, S, or a combination thereof.

As used herein, when a definition is not otherwise provided, “heteroaryl” and “heteroarylene” refer to a monovalent and polyvalent (e.g., divalent) cyclic aromatic system with a heteroatom such as N, O, P, Si, B, Se, Ge, Te, S, or a combination thereof as a ring forming atom, respectively. When the heteroaryl group or heteroarylene includes a plurality of rings, the plurality of rings may be fused to each other. In an embodiment, the heteroaryl or the heteroarylene group may have 3 to 50 carbon atoms, or 6 to 18 carbon atoms, or 6 to 12 carbon atoms. Examples of heteroaryl groups include a pyridinyl group, a pyrimidinyl group, a pyrazinyl group, a pyridazinyl group, a triazinyl group, a quinolinyl group, and an isoquinolinyl group.

As used herein, when a definition is not otherwise provided, “alkoxy” refers to an alkyl group linked to oxygen (e.g., alkyl-O—) for example, a methoxy group, an ethoxy group, or a sec-butyloxy group.

As used herein, when a definition is not otherwise provided, “amine” is a compound represented by NR₃, wherein each R is independently hydrogen, a C1-C12 alkyl group, a C7-C20 alkylaryl group, a C7-C20 arylalkyl group, or a C6-C18 aryl group.

As used herein, the term “peak emission wavelength” is the wavelength at which a given emission spectrum of the light reaches its maximum.

As used herein, the expression “not including cadmium (or other harmful heavy metal)” means that a concentration of cadmium (or another heavy metal deemed harmful) may be less than or equal to about 100 parts per million by weight (“ppmw”), less than or equal to about 50 ppmw, less than or equal to about 10 ppmw, less than or equal to about 1 ppmw, less than or equal to about 0.1 ppmw, less than or equal to about 0.01 ppmw, or zero. In an embodiment, substantially no amount of cadmium (or other toxic heavy metal) may be present or, if present, an amount of cadmium (or other heavy metal) may be less than or equal to a detection limit or as an impurity level of a given analysis tool (e.g., an inductively coupled plasma atomic emission spectroscopy instrument).

Unless mentioned to the contrary, a numerical range recited herein is inclusive.

Unless mentioned to the contrary, a numerical range recited herein includes any real number within the endpoints of the stated range and includes the endpoints thereof. In this specification, a numerical endpoint or an upper or lower limit value (e.g., recited either as a “greater than or equal to value”, “at least value” or a “less than or equal to value” or recited with “from” or “to”) may be used to form a numerical range of a given feature. In other words, the upper and lower endpoints set forth for various numerical values may be independently combined to provide a range.

As used herein, the term “Group” may refer to a group of Periodic Table.

As used herein, “Group I” refers to Group IA and Group IB, and examples may include Li, Na, K, Rb, and Cs, but are not limited thereto.

As used herein, “Group II” refers to Group IIA and Group IIB, and examples of Group II metal may be Cd, Zn, Hg, and Mg, but are not limited thereto.

As used herein, “Group III” refers to Group IIIA and Group IIIB, and examples of Group IIIA metal may be Al, In, Ga, and TI, and examples of Group IIIB may be scandium, yttrium, or the like, but are not limited thereto.

As used herein, “Group IV” refers to Group IVA and Group IVB, and examples of a Group IVA metal may be Si, Ge, and Sn, and examples of Group IVB metal may be titanium, zirconium, hafnium, or the like, but are not limited thereto.

As used herein, “Group V” includes Group VA and includes nitrogen, phosphorus, arsenic, antimony, and bismuth, but is not limited thereto.

As used herein, “Group VI” includes Group VIA and includes sulfur, selenium, and tellurium, but is not limited thereto.

As used herein, “metal” includes a semi-metal such as Si.

As used herein, a nanoparticle is a structure having a, e.g., at least one, region or characteristic dimension with a nanoscale dimension. In an embodiment, a dimension (or an average dimension) of the nanostructure is less than or equal to about 500 nanometers (nm), less than or equal to about 300 nm, less than or equal to about 250 nm, less than or equal to about 150 nm, less than or equal to about 100 nm, less than or equal to about 50 nm, or less than or equal to about 30 nm, and may be greater than about 0.1 nm or greater than or equal to about 1 nm.

The nanoparticle may have any suitable shape.

The nanoparticle (e.g., a semiconductor nanoparticle or a metal oxide nanoparticle) may include a nanowire, a nanorod, a nanotube, a branched nanostructure, a nanotetrapod, a nanotripod, a nanobipod, a nanodot, a multi-pod type shape such as at least two pods, or the like and is not limited thereto. The nanoparticle can be, e.g., substantially crystalline or crystalline, substantially monocrystalline or monocrystalline, polycrystalline, (for example, at least partially) amorphous, or a combination thereof.

A semiconductor nanoparticle such as a quantum dot can be a type of a nanostructure and may exhibit quantum confinement or exciton confinement. As used herein, the term “quantum dot” or “semiconductor nanostructure” is not limited in a shape thereof unless otherwise defined. A semiconductor nanoparticle or a quantum dot may have a size smaller than a Bohr excitation diameter for a bulk crystal material having an identical composition and may exhibit a quantum confinement effect.

The quantum dot or the semiconductor nanoparticle includes a semiconductor nanocrystal acting as an emission center and may be configured to emit light of a desired wavelength depending on a size and/or a composition of the semiconductor nanocrystal. The emission center may include or may not include a dopant. The presence of the dopant may not substantially affect an peak emission wavelength of the semiconductor nanocrystal, and the change in the emission wavelength according to the presence of the dopant may be less than or equal to about 10 nm, less than or equal to about 7 nm, less than or equal to about 5 nm, less than or equal to about 3 nm, less than or equal to about 1 nm, less than or equal to about 0.5 nm, or about 0 nm.

As used herein, the term, quantum efficiency, may be used interchangeably with the term, quantum yield. The quantum efficiency may be a relative quantum yield or an absolute quantum yield, which can be readily measured by any suitable, e.g., commercially available, equipment. The quantum efficiency (or quantum yield) may be measured in a solution state or a solid state (in a composite). As used herein, “quantum yield (or quantum efficiency)” may be a ratio of photons emitted relative to photons absorbed, e.g., by a nanostructure or population of nanostructures. The quantum efficiency may be determined by any suitable method. For example, there may be two methods for measuring the fluorescence quantum yield or efficiency: an absolute method and a relative method.

The absolute method directly obtains the quantum yield by detecting all sample fluorescence through the use of an integrating sphere. In the relative method, the fluorescence intensity of a standard sample (e.g., a standard dye) may be compared with the fluorescence intensity of an unknown sample to calculate the quantum yield of the unknown sample. Coumarin 153, Coumarin 545, Rhodamine 101 inner salt, Anthracene, and Rhodamine 6G may be used as the standard dye, depending on the photoluminescence (“PL”) wavelengths thereof, but are not limited thereto.

A bandgap energy of a semiconductor nanoparticle may vary depending on a size and/or a composition of a nanocrystal. For example, as a size of the semiconductor nanoparticle increases, the bandgap energy of the semiconductor nanoparticle may become smaller, e.g., narrower, and the semiconductor nanoparticle may emit light, e.g., having an increased emission wavelength. A semiconductor nanocrystal may be used as a light emitting material in various fields, such as in, a display device, an energy device, or a bio light emitting device.

The application of the semiconductor nanoparticle in an electronic device or an optoelectronic device may involve a process of providing a high-resolution patterned film. An inkjet printing, a photolithography, or the like may be considered for providing a patterned semiconductor nanoparticle film. For example, an organic polymer or an organic monomer-based photoresist may be applied on a substrate to obtain a thin film, and then the obtained thin film may be selectively exposed to radiation (e.g., using a photomask) and then the unexposed portion may be removed by contacting with a developer to obtain a desired pattern (e.g., a photopolymer mask pattern, which can be used as a photopolymer mask to form a pattern of semiconductor nanoparticles). However, in such a photolithography process, the polymer may swell in the presence of a solvent, and as the pattern size decreases, the pattern resolution can be compromised because the action of the capillary force of the dispersion solvent on the photopolymer pre-pattern wall may have an increasingly dominant effect on the pattern shape. Therefore, it is desired to develop a method of producing a patterned semiconductor nanoparticle film without using a substantial amount of conventional, polymer- or monomer-based photoresists.

A photolithography process may often induce significant surface damage to the deposited emissive nanomaterials, and thereby may degrade their optical properties such as a light emitting efficiency or a photoluminescent quantum yield. In certain circumstances, a light emitting material (e.g., a colloidal perovskite nanocrystal particle) may have labile surface ligands and weak lattice energy character based on an ionic bonding, thus during the patterning process, a loss in the light emitting properties PLQY may occur. Therefore, it is desirable to develop a patterning method without causing a substantial damage to the optical properties of nanomaterials.

The method as disclosed herein can meet the above-described technical requirements. In particular, the method can enable a photocatalytic patterning for a light-emitting nanomaterial such as a semiconductor nanoparticle. In the method, a dual role click chemical reagent (e.g., the additive) may serve as both a crosslinking agent and a defect passivation agent. Without wishing to be bound by theory, during radiation exposure as described herein, excitons generated from the light-emitting nanomaterial can photo-catalytically assist the formation of thiyl radicals, and thereby a reaction between the additive and the reactive moiety (e.g., carbon-carbon double bonds) of the organic ligand as described herein may occur, for example at a relatively low radiation dose. Accordingly, a pattern of light-emitting nanomaterials (e.g., a patterned film of the light emitting materials) can be obtained, and the obtained pattern can exhibit enhanced properties.

The method as described herein can provide a pattern (e.g., a patterned film) of various luminescent nanomaterials (e.g., a semiconductor nanocrystal particle), while reducing or preventing a loss of the optical properties of the nanomaterials. The manufactured pattern (e.g., a RGB pattern) can be used as a light emitting element for example in an electronic device (e.g., a photodiode) including a light source, a display, or a self, light-emitting electronic device (e.g., a QD-LED) capable of emitting light with or without a light source.

Thus, the patterning method (or a method of producing a patterned film) may provide a film including a first region configured to emit the first light. The film may further include a second region configured to emit the second light different from the first light. The film may further include a third region configured to emit the third light different from the first light and the second light. The first light, the second light, and the third light may each independently have a red light spectrum, a green light spectrum, or a blue light spectrum. As used herein, the description of the first light may be applied to the second light and the third light, respectively.

The first light may have a predetermined peak emission wavelength. A full width at half maximum of (the emission peak of) the first light may be greater than or equal to about 1 nm, greater than or equal to about 5 nm, greater than or equal to about 10 nm, greater than or equal to about 15 nm to less than or equal to about 70 nm, less than or equal to about 65 nm, less than or equal to about 60 nm, less than or equal to about 55 nm, less than or equal to about 50 nm, less than or equal to about 45 nm, less than or equal to about 40 nm, less than or equal to about 35 nm, or less than or equal to about 30 nm.

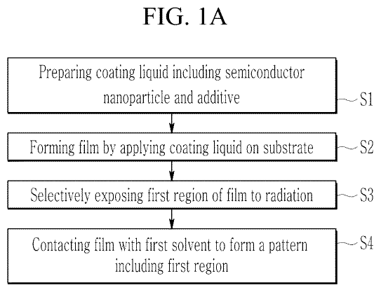

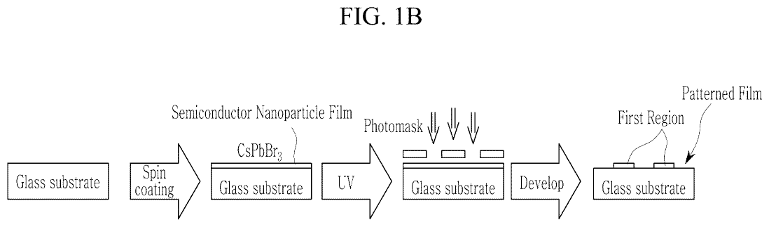

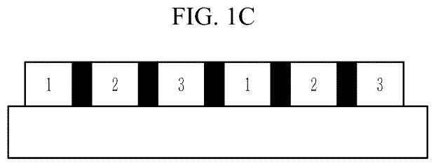

An embodiment of the patterning method includes:
forming a first film containing an additive and a semiconductor nanoparticle, wherein the additive includes a polythiol compound containing two or more thiol groups, and wherein the semiconductor nanoparticle is configured to emit the first light, and the semiconductor nanoparticle includes an organic ligand on a surface thereof, and wherein the organic ligand includes a carbon-carbon unsaturated bond and a first functional group bonded to the surface of the semiconductor nanoparticle (for example, S2 in FIG. 1A);
exposing a portion of the first film corresponding to the first region to radiation to change a solubility of the semiconductor nanoparticle in the first region (or in an exposed area) with respect to the first solvent (for example, S3 in FIG. 1A);
contacting the radiation treated film with the first solvent (e.g., removing an unexposed portion excluding the first region or at least a portion thereof) (for example, S4 in FIG. 1A) to obtain a patterned film including the first region.

In the method, the formation of the film may include preparing a coating composition or a coating liquid including the semiconductor nanoparticles and the additive S1, and applying the coating composition on a substrate to form a film S2. (see FIGS. 1A and 1B).

The patterning method (or the method of preparing a patterned film) may not involve the use of a photoresist including a polymer or a monomer. The coating composition may not include an electrically insulating (hereinafter, referred to as insulating) polymer or a monomer thereof. The insulating property of the polymer may be a technical limitation in the manufacture of an electroluminescent device, and can reduce a density (e.g., a number density) of the light emitting material (i.e., a semiconductor nanoparticle) for example, in a light emitting layer. In addition, the low refractive index property of the polymer may have an adverse effect on a photo-conversion film or on a display application, for example, by reducing light extraction efficiency or widening the emission angle. In an embodiment, the method can provide the patterned film without the use of such a polymer, maintaining the optical properties of the nanomaterial (i.e., the semiconductor nanoparticle) at a desired level. In the patterning method of an embodiment, a chemical change in the portion exposed by radiation (e.g., the first region) may lead to a change in a dissolution property (e.g., solubility) of the film to the solvent, and a desired pattern of semiconductor nanoparticles can be formed based on the changed solubility. Such a method may include fewer process steps than the conventional method involving the use of the photoresist, and may increase the amount of the light emitting material (semiconductor nanoparticle) in the formed pattern. However, the present inventors have found that the direct exposure of the radiation to a film containing a semiconductor nanoparticle may have an adverse effect on the optical properties (e.g., light emitting efficiency) of the semiconductor nanoparticles. Without wishing to be bound by any theory, it is believed that not only can radiation affect the properties of the semiconductor nanoparticle (for example, its surface properties) but also that photochemical reaction products due to the irradiation may cause a decrease in the properties of semiconductor nanoparticle. In the method of an embodiment, radiation can be irradiated to the film as described herein to provide a high-quality (e.g., with a resolution of less than about 10 micrometers) pattern while maintaining or improving the optical properties of the semiconductor nanoparticle.

The substrate is not particularly limited and may be appropriately selected taking into consideration the final application of the pattern. The substrate may include an insulating material, a conductive (e.g., an electrically conductive) material, or a combination thereof. The substrate may include an organic material, an inorganic material, or a combination thereof. In an embodiment, the manufactured film pattern may be included in an electroluminescent device, and the substrate may include an electrode and a charge transport layer, if desired, but is not limited thereto.

In the method, the semiconductor nanoparticle may include a first semiconductor nanocrystal. The semiconductor nanoparticle may have a core-shell structure. In an embodiment, the semiconductor nanoparticle (or the core-shell structure) may include a first semiconductor nanocrystal (or core including the same) and a shell disposed on the first semiconductor nanocrystal (or the core) and including a second semiconductor nanocrystal having a composition different from that of the first semiconductor nanocrystal.

The semiconductor nanoparticle may have a core-shell structure, and at an interface between the core and the shell, an alloyed interlayer may exist or may not exist. The alloyed interlayer layer may include a homogeneous alloy or may have a concentration gradient. The gradient alloy may have a concentration gradient wherein the concentration of an element of the shell varies radially (e.g., decreases or increases in a direction toward the core).

Optionally, the shell may have a composition that varies in a radial direction. The shell may be a multilayered shell including two or more layers. In a multilayered shell, adjacent two layers may have different compositions from each other. In a multilayered shell, a, e.g., at least one, layer may independently include a semiconductor nanocrystal having a single composition. In a multilayered shell, a, e.g., at least one, layer may independently have an alloyed semiconductor nanocrystal. In a multilayered shell, a, e.g., at least one, layer may have a concentration gradient that varies radially in terms of a composition of a semiconductor nanocrystal.

As an example, in a semiconductor nanoparticle having a core-shell structure, a shell material may have a bandgap energy that is larger, e.g., greater, than that of the core. The materials of the shell may have a bandgap energy that is smaller, e.g., less, than that of the core. In the case of a multilayered shell, the bandgap energy of the outermost layer material of the shell may be greater than the bandgap energies of the core and the inner layer material of the shell (layers that are closer to the core). In the case of a multilayered shell, a semiconductor nanocrystal of each layer may be selected to have an appropriate bandgap, thereby effectively showing, e.g., exhibiting, a quantum confinement effect.

The semiconductor nanoparticle, the first semiconductor nanocrystal, and/or the second semiconductor nanocrystal may independently include a Group II-VI compound, a Group III-V compound, a Group IV-VI compound, a Group IV element or compound, a Group I-III-VI compound, a Group II-III-VI compound, a Group I-II-IV-VI compound, a metal halide perovskite compound, a transition metal chalcogenide perovskite compound, or a combination thereof. The semiconductor nanoparticle may or may not include a harmful heavy metal such as cadmium, lead, mercury, or a combination thereof.

The Group II-VI compound may be a binary element compound such as ZnS, ZnSe, ZnTe, ZnO, HgS, HgSe, HgTe, MgSe, MgS, or a combination thereof; a ternary element compound such as ZnSeS, ZnSeTe, ZnSTe, HgSeS, HgSeTe, HgSTe, HgZnS, HgZnSe, HgZnTe, MgZnSe, MgZnS, or a combination thereof; a quaternary element compound such as HgZnTeS, HgZnSeS, HgZnSeTe, HgZnSTe, or a combination thereof; or a combination thereof. The Group II-VI compound may further include a Group III metal.

The Group III-V compound may be a binary element compound such as GaN, GaP, GaAs, GaSb, AlN, AIP, AlAs, AlSb, InN, InP, InAs, InSb, or a combination thereof; a ternary element compound such as GaNP, GaNAs, GaNSb, GaPAs, GaPSb, AlNP, AlNAs, AlNSb, AlPAS, AlPSb, InNP, InNAs, InNSb, InPAs, InPSb, or a combination thereof; a quaternary element compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or a combination thereof; or a combination thereof. The Group III-V compound may further include a Group II metal (e.g., InZnP).

The Group IV-VI compound may be a binary element compound such as SnS, SnSe, SnTe, PbS, PbSe, PbTe, or a combination thereof; a ternary element compound such as SnSeS, SnSeTe, SnSTe, PbSeS, PbSeTe, PbSTe, SnPbS, SnPbSe, SnPbTe, or a combination thereof; a quaternary element compound such as SnPbSSe, SnPbSeTe, SnPbSTe, or a combination thereof; or a combination thereof.

Examples of the Group I-III-VI compound may be CuInSe₂, CuInS₂, CuInGaSe, and CuInGaS, but are not limited thereto.

Examples of the Group I-II-IV-VI compound may be CuZnSnSe, and CuZnSnS, but are not limited thereto.

The Group IV element or compound may include a single element such as Si, Ge, or a combination thereof; a binary element compound such as SiC, SiGe, or a combination thereof; or a combination thereof.

The metal halide perovskite compound may be represented by Chemical Formula 1:

ABX₃. Chemical Formula 1

In Chemical Formula 1, A is an alkali metal, the NR⁴⁺, [CH(NH₂)₂]⁺, an organic guanidium (guanidium), or a combination thereof, B is a transition metal, a group IVA metal, an alkaline earth metal, a rare earth metal, or a combination thereof. X is at least one halogen selected from F, Cl, Br, and I, R is the same or different, and is hydrogen or a C1-C10 alkyl group, such as a methyl group.

The alkali metal may include Rb, Cs, Fr, or a combination thereof. The IVA group metal may include Ge, Si, Sn, Pb, or a combination thereof.

The metal halide perovskite compound may be CsPbCl₃, CsPbBr₃, CsPbI₃, CsPb(Cl,I)₃, CsPb(Br,I)₃, CsPb(Br,Cl)₃, or a combination thereof.

As used herein, “(Cl,I), (Br,I), or (Br,I)” means that the compound includes two kinds of halogens (i.e., Cl and I, Br and I, or Br and Cl), and in the case where the compound includes two kinds of halogens (X1, X2), the molar ratio of both is not particularly limited.

The transition metal chalcogenide may include a compound represented by Chemical Formula 2:

M1M2Cha3 Chemical Formula 2

In Chemical Formula 2, M1 is Ca, Sr, Ba, or a combination thereof,
M₂ is Ti, Zr, Hf, or a combination thereof, and
Cha is S, Se, Te, or a combination thereof.

The transition metal chalcogenide may include BaZrS₃, SrZrS₃, CaZrS₃, SrTiS₃, BaTiS₃, or BaZr₁₋ₓTiₓS₃ (where x is greater than 0 and less than or equal to about 0.5); BaZrSe₃, SrZrSe₃, CaZrSe₃, SrTiSe₃, BaTiSe₃, or BaZr₁₋ₓTiₓSe₃ (where x is greater than 0 and less than or equal to about 0.5); BaZrTe₃, SrZrTe₃, CaZrTe₃, SrTiTe₃, BaTiTe₃, or BaZr₁₋ₓTiₓTe₃ (where x is greater than 0 and less than or equal to about 0.5); or a combination thereof.

The semiconductor nanoparticles including the metal halide compound or the transition metal chalcogenide may include, for example, a perovskite crystal structure confirmed by an X-ray diffraction spectrum.

In an embodiment, the semiconductor nanoparticle or the first semiconductor nanocrystal may include a metal including indium, zinc, or a combination thereof and a non-metal including phosphorus, selenium, tellurium, sulfur, or a combination thereof. In an embodiment, the semiconductor nanoparticle or the second semiconductor nanocrystal may include a metal including indium, zinc, or a combination thereof, and a non-metal including phosphorus, selenium, tellurium, sulfur, or a combination thereof.

In an embodiment, the semiconductor nanoparticle or the first semiconductor nanocrystal may include InP, InZnP, ZnSe, ZnSeS, ZnSeTe, a metal halide perovskite compound, a transition metal chalcogenide perovskite compound or a combination thereof; the second semiconductor nanocrystal may include ZnSe, ZnSeS, ZnS, ZnTeSe, or a combination thereof. In an embodiment, the semiconductor nanoparticle or the shell may include zinc, sulfur, and optionally selenium in the outermost layer.

In an embodiment, the semiconductor nanoparticle may adjust an absorption/emission wavelength by adjusting, for example, its composition and/or size. The semiconductor nanoparticle may be configured to emit light (first light) of a desired color.

In an embodiment, the semiconductor nanoparticle or a (pre-determined) peak emission wavelength of the first light (or second light or third light) may have a wavelength range of ultraviolet to infrared wavelengths or greater. In an embodiment, the (predetermined) peak emission wavelength may be greater than or equal to about 300 nm, greater than or equal to about 500 nm, greater than or equal to about 510 nm, greater than or equal to about 520 nm, greater than or equal to about 530 nm, greater than or equal to about 540 nm, greater than or equal to about 550 nm, greater than or equal to about 560 nm, greater than or equal to about 570 nm, greater than or equal to about 580 nm, greater than or equal to about 590 nm, greater than or equal to about 600 nm, or greater than or equal to about 610 nm. The peak emission wavelength may be less than or equal to about 900 nm, less than or equal to about 800 nm, less than or equal to about 650 nm, less than or equal to about 640 nm, less than or equal to about 630 nm, less than or equal to about 620 nm, less than or equal to about 610 nm, less than or equal to about 600 nm, less than or equal to about 590 nm, less than or equal to about 580 nm, less than or equal to about 570 nm, less than or equal to about 560 nm, less than or equal to about 550 nm, or less than or equal to about 540 nm. The peak emission wavelength may be from about 500 nm to about 650 nm.

The semiconductor nanoparticle may emit green light (for example, on an application of a voltage or irradiation with light). A peak emission wavelength of the green light may be in the range of greater than or equal to about 500 nm (for example, greater than or equal to about 510 nm, greater than or equal to about 515 nm, greater than or equal to about 520 nm, or greater than or equal to about 525 nm) and less than or equal to about 560 nm, for example, less than or equal to about 540 nm, or less than or equal to about 530 nm.

The semiconductor nanoparticle may emit red light, (for example, on an application of voltage or irradiation with light), and a peak emission wavelength of the red light may be in the range of greater than or equal to about 600 nm, for example, greater than or equal to about 610 nm and less than or equal to about 650 nm, or less than or equal to about 640 nm.

The semiconductor nanoparticle may emit blue light, (for example, on an application of voltage or irradiation with light) and a peak emission wavelength thereof may be greater than or equal to about 440 nm (for example, greater than or equal to about 450 nm, greater than or equal to about 455 nm, greater than or equal to about 460 nm, or greater than or equal to about 465 nm) and less than or equal to about 480 nm (for example, less than or equal to about 475 nm, less than or equal to about 470 nm, or less than or equal to about 465 nm).

In an embodiment, the semiconductor nanoparticle may exhibit a luminescent spectrum (e.g., photo- or electro-luminescent spectrum) with a relatively narrow full width at half maximum. In an embodiment, in the photo- or electro-luminescent spectrum, the semiconductor nanoparticle may exhibit a full width at half maximum of less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, less than or equal to about 35 nm, less than or equal to about 30 nm, less than or equal to about 25 nm, or less than or equal to about 20 nm. The full width at half maximum may be greater than or equal to about 1 nm, greater than or equal to about 5 nm, greater than or equal to about 10 nm, or greater than or equal to about 15 nm.

The semiconductor nanoparticle may exhibit (or may be configured to exhibit) a quantum efficiency (or quantum yield) of greater than or equal to about 10%, for example, greater than or equal to about 30%, greater than or equal to about 50%, greater than or equal to about 60%, greater than or equal to about 70%, greater than or equal to about 80%, greater than or equal to about 90%, or about 100%.

The semiconductor nanoparticle may have a size (or an average size, hereinafter, “size”) of greater than or equal to about 1 nm and less than or equal to about 100 nm. The size may be a diameter or equivalent diameter converted by assuming a spherical shape from an electron microscope image when not spherical. The size may be calculated from a result of an inductively coupled plasma atomic emission spectroscopy (“ICP-AES”) analysis and an optical analysis (e.g., UV-Vis absorption spectroscopy analysis). In an embodiment, the quantum dot may have a size of from about 1 nm to about 50 nm, for example, from about 2 nm (or about 3 nm) to about 35 nm. In an embodiment, a size (or an average size) of the quantum dot may be greater than or equal to about 3 nm, greater than or equal to about 4 nm, greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, or greater than or equal to about 12 nm. In an embodiment, a size of the quantum dot may be less than or equal to about 50 nm, less than or equal to about 40 nm, less than or equal to about 30 nm, less than or equal to about 25 nm, less than or equal to about 20 nm, less than or equal to about 19 nm, less than or equal to about 18 nm, less than or equal to about 17 nm, less than or equal to about 16 nm, less than or equal to about 15 nm, less than or equal to about 14 nm, less than or equal to about 13 nm, or less than or equal to about 12 nm.

The shape of the semiconductor nanoparticle is not particularly limited. For example, the shape of the quantum dot may include, but is not limited to, a sphere, a polyhedron, a pyramid, a multi-pod shape, a hexahedron, a cube, a cuboid, a nanotube, a nanorod, a nanowire, a nanosheet, or a combination thereof.

The semiconductor nanoparticle may be synthesized by any method, which is not particularly limited. In an embodiment, the semiconductor nanocrystal having a size of several nanometers may be synthesized through a wet chemical process. In the wet chemical process, a semiconductor nanocrystal particle or nanoparticle may be grown by reacting precursor materials in an organic solvent, and growth of a nanocrystal may be controlled by coordinating the organic solvent or ligand compound on the surface of the nanoparticle. The wet chemical process may include a hot injection, a ligand assisted reprecipitation, or a combination thereof.

The method of recovering the manufactured semiconductor nanoparticles is not particularly limited. In an embodiment, a non-solvent may be added to the reaction product after the reaction is completed, and the semiconductor nanoparticle coordinated with an organic matter such as the ligand compound may be separated. The nonsolvent may be a polar solvent that is miscible with the solvent used in the core formation and/or shell formation reactions and is not capable of dispersing the prepared nanocrystals. The nonsolvent may be selected depending on the solvent used in the reaction and may include, for example, acetone, ethanol, butanol, isopropanol, ethanediol, water, tetrahydrofuran (THF), dimethylsulfoxide (DMSO), diethylether, formaldehyde, acetaldehyde, a solvent having a similar solubility parameter to the foregoing non-solvents, or a combination thereof. The recovery or the separation of the semiconductor nanocrystal particle or the quantum dot may include centrifugation, sedimentation, chromatography, or distillation. The separated nanocrystal or quantum dot may be added to a washing solvent and washed, if needed. Types of the washing solvent are not particularly limited and may be selected from the ones having a similar solubility parameter to that of the ligand and may, for example, include hexane, heptane, octane, chloroform, toluene, benzene, and the like.

In an embodiment, the semiconductor nanoparticle may include an organic ligand on a surface thereof. The organic ligand may be coordinated or bonded to the surface of the semiconductor nanoparticle. The organic ligand may be a ligand that is provided on the surface of the semiconductor nanoparticles in the process of synthesizing the semiconductor nanoparticles.

The organic ligand may include a first functional group and a carbon-carbon unsaturated bond, where the organic ligand can be bonded to a surface of a semiconductor nanoparticle via the first functional group. As used in the disclosure, “bonded” means that the organic ligand can be non-covalently or covalently bonded to a surface of the semiconductor nanoparticle. The bonding can be based on van der Walls forces, hydrogen bonding, ionic interactions, dipole-dipole interactions, and/or a coordinate bond. The first functional group may include a carboxyl group, a thiol group, an amine group, a phosphine group, a phosphine oxide group, an ester group (e.g., a carboxylic ester group), a hydroxyl group, or a combination thereof. The carbon-carbon unsaturated bond may include or may be a carbon-carbon double bond. The organic ligand may react with the additive described herein when the semiconductor nanoparticle (which includes the organic ligand) and the additive are exposed to a radiation, and accordingly, the radiation may cause a change in solubility of the semiconductor nanoparticle in the first solvent.

The organic ligand may include RCOOH, RNH₂, R₂NH, R₃N, RSH, RH₂PO, R₂HPO, R₃PO, RH₂P, R₂HP, R₃P, ROH, RCOOR′, RPO(OH)₂, R₂POOH, or a combination thereof, wherein, each R and R′ independently can be a substituted or unsubstituted, C1 or more, C6 or more, or C10 or more and C40 or less, C35 or less, or C25 or less aliphatic hydrocarbon group, or a substituted or unsubstituted C6 to C40 aromatic hydrocarbon group, or a combination thereof, provided that R, R′, or both may include a carbon-carbon unsaturated bond, for example a carbon-carbon double bond. The aliphatic hydrocarbon may have a carbon number in a range of C5-C40, C8-C30, C10-C25, C12-C20, C14-C18, or a combination thereof.

The aliphatic hydrocarbon group may be a linear or branched hydrocarbon group containing one or more carbon-carbon unsaturated bond(s) in the carbon chain or at a terminal of the carbon chain, for example. The organic ligand may be used alone or as a mixture of at least two compounds. R or R′ may each independently include ethenyl, propenyl, butenyl, pentenyl, hexenyl, heptenyl, octenyl, nonenyl, decenyl, undecenyl, dodecenyl, tridecenyl, pentadecenyl, hexadecenyl, heptadecenyl, octadecenyl, or nonadecenyl. The organic ligand may include a carboxylic acid compound with a C3-C30, C6-C25, C8-C22, C10-C20, C15-C18 alkenyl or alkenylene group, such as propenoic acid, butenoic acid, pentenoic acid, hexenoic acid, heptenoic acid, octenoic acid, nonenoic acid, decenoic acid, undecenoic acid, dodecenoic acid, tridecenoic acid, tetradecenoic acid, pentadecenoic acid, hexadecenoic acid, heptadecenoic acid, octadecenoic acid (e.g., oleic acid); a thiol compound with a C3-C30, C6-C25, C8-C22, C10-C20, or C15-18 alkenyl or alkenylene group; an amine compound with a C3-C30, C6-C25, C8-C22, C10-C20, or C15-C18 alkenyl or alkenylene group, for example, oleylamine; a phosphine compound with a C3-C30, C6-C25, C8-C22, C10-C20, or C15-C18 alkenyl or alkenylene group; an alcohol compound with a C3-C30, C6-C25, C8-C22, C10-C20, or C15-C18 alkenyl or alkenylene group; an ester compound having a C3-C30, C6-C25, C8-C22, C10-C20, or C15-C18 alkenyl or alkenylene group; or a combination thereof.

The semiconductor nanoparticles may be dispersed in a first solvent to be described later by including, for example, the organic ligand on the surface thereof.

A semiconductor nanoparticle (e.g., a metal halide perovskite nanocrystal) has been attracting attention as a next-generation light emitting material. A semiconductor nanoparticle can exhibit an improved quantum yield, a narrow light emission peak, a color tunability, and a solution processability. However, a micro-scale patterning technology for semiconductor nanoparticles still has room for development for applications in an actual display and a photoelectric device. The photolithography process of the prior art has many drawbacks in patterning for inorganic nanocrystals (e.g., problems of non-uniform pattern formation due to capillary force or swelling of photoresists). In addition, when it is desired to provide a pattern of semiconductor nanoparticles by applying a photolithography technology, it is likely to be accompanied by deterioration in the physical properties of the semiconductor nanoparticles. Surprisingly, the present inventors have found that an improved quality film pattern can be formed without a substantial decrease in light emitting properties thereof by irradiating radiation to a film containing an additive as described herein along with the semiconductor nanoparticle described herein

Accordingly, in the patterning method, the film further includes an additive having a thiol group. The additive may include a polythiol compound containing two or more thiol groups. In an embodiment, the additive may include or may not include a monothiol compound having one thiol group. The polythiol compound may include a dithiol compound, a trithiol compound, a tetrathiol compound, or a combination thereof. In an embodiment, a photocatalytic reaction between the additive and the organic ligand may be promoted by the semiconductor nanoparticle, and thus the reaction may occur at a relatively low radiation dose.

The additive or the polythiol compound may have a molecular weight of greater than or equal to about 10 g/mol, greater than or equal to about 50 g/mol, greater than or equal to about 100 g/mol, greater than or equal to about 150 g/mol, greater than or equal to about 200 g/mol, greater than or equal to about 250 g/mol, greater than or equal to about 300 g/mol, greater than or equal to about 350 g/mol, greater than or equal to about 400 g/mol, greater than or equal to about 450 g/mol, greater than or equal to about 500 g/mol, or greater than or equal to about 550 g/mol. The additive or the polythiol compound may have a molecular weight of less than or equal to about 5,000,000 g/mol, less than or equal to about 1,000,000 g/mol, less than or equal to about 500,000 g/mol, less than or equal to about 100,000 g/mol, less than or equal to about 50,000 g/mol, less than or equal to about 10,000 g/mol, less than or equal to about 5,000 g/mol, less than or equal to about 4,500 g/mol, less than or equal to about 4,000 g/mol, less than or equal to about 3,500 g/mol, less than or equal to about 3,000 g/mol, less than or equal to about 2,500 g/mol, less than or equal to about 2,000 g/mol, less than or equal to about 1,750 g/mol, less than or equal to about 1,500 g/mol, less than or equal to about 1,250 g/mol, less than or equal to about 1,000 g/mol, less than or equal to about 750 g/mol, less than or equal to about 700 g/mol, less than or equal to about 500 g/mol, less than or equal to about 400 g/mol, less than or equal to about 300 g/mol, or less than or equal to about 250 g/mol.

The polythiol compound may further include —O—, —CO—, —COO—, —NR—, —CONR— (where R in —NR— and —CONR— is independently a hydrogen or C1 to C10 hydrocarbon group), a substituted or unsubstituted C1-C40 or C5-C20 alkylene group, a substituted or unsubstituted C2-C40 or C5-C20 alkenylene group, a substituted or unsubstituted C2-C40 or C5-C20 alkynylene group, or a combination thereof (e.g., any combination of the aforementioned moieties).

As used herein, the wording “a combination thereof” may mean a moiety formed by bonding at least two or more of the listed moieties. Thus, for example, the polythiol compound may include a moiety formed by linking the alkylene moiety and the alkenylene moiety directly or via —O—, —CO—, —CO—, —NR—, —CONR—, (where R is hydrogen or a C1 to C10 hydrocarbon group). In addition, for example, the polythiol compound may include a substituted or unsubstituted alkylene moiety (or an alkenylene moiety or an alkynylene moiety) wherein at least one methylene group is replaced with —O—, —CO—, —COO—, —NR—, —CONR—, (where R is hydrogen or a C1 to C10 hydrocarbon group).

The polythiol compound may include a central moiety and at least one (e.g., two or more) HS—R—* (where R is a substituted or unsubstituted C1 to C30 aliphatic hydrocarbon group bonded to the central moiety; a substituted or unsubstituted C2 to C30 aliphatic hydrocarbon group at least one methylene replaced with a sulfonyl, carbonyl, ether, sulfide, sulfoxide, ester, amide, or a combination thereof; or a combination thereof). The central moiety may include a carbon atom, a substituted or unsubstituted C1 to C30 aliphatic hydrocarbon group, a substituted or unsubstituted C3 to C30 alicyclic hydrocarbon group, a substituted or unsubstituted C6 to C30 aromatic hydrocarbon group, a substituted or unsubstituted C3 to C30 heteroarylene group, a substituted or unsubstituted C3 to C30 heterocyclic group, or a combination thereof.

The polythiol compound may include a dimercaptoacetate compound, a trimercaptoacetate compound, a tetramercaptoacetate compound, a dimercaptopropionate compound, a trimercaptopropionate compound, a tetramercaptopropionate compound, an isocyanate compound including two or more mercaptoalkylcarbonyloxyalkyl groups, an isocynurate compound including two or more mercaptoalkylcarbonyloxyalkyl groups, or a combination thereof.

The thiol compound may be represented by Chemical Formula 3:

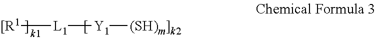

wherein, in Chemical Formula 3, R¹ is hydrogen, a substituted or unsubstituted C1 to C30 linear or branched alkyl group, a substituted or unsubstituted C6 to C30 aryl group, a substituted or unsubstituted C7 to C30 arylalkyl group, a substituted or unsubstituted C3 to C30 heteroaryl group, a substituted or unsubstituted C3 to C30 cycloalkyl group, a substituted or unsubstituted C3 to C30 heterocycloalkyl group, a substituted or unsubstituted C1 to C10 alkoxy group, a hydroxy group, —NH₂, a substituted or unsubstituted C1 to C30 amine group (—NRR′, wherein R and R′ are independently hydrogen or a C1 to C30 linear or branched alkyl group, and are not simultaneously hydrogen), an isocyanate group, a halogen, —ROR′ (wherein R is a substituted or unsubstituted C1 to C20 alkylene group and R′ is hydrogen or a C1 to C20 linear or branched alkyl group), an acyl halide group (—RC(═O) X, wherein R is a substituted or unsubstituted C1 to C20 alkylene group and X is a halogen), —C(═O) OR′ (wherein R′ is hydrogen or a C1 to C20 linear or branched alkyl group), —CN, —C(═O) NRR′ or —C(═O)ONRR′ (wherein R and R′ are independently hydrogen or a C1 to C20 linear or branched alkyl group), or a combination thereof,
L₁ is a carbon atom, a substituted or unsubstituted C1 to C30 alkylene group, a substituted or unsubstituted C2 to C30 alkenylene group, a substituted or unsubstituted C3 to C30 cycloalkylene group, a substituted or unsubstituted C6 to C30 arylene group, a substituted or unsubstituted C3 to C30 heteroarylene group (e.g., quinoline, quinolone, triazine, triazinetrione moiety, etc.), a C3 to C30 heterocycloalkylene group, or a substituted or unsubstituted C2 to C30 alkylene group or a substituted or unsubstituted C3 to C30 alkenylene group where at least one methylene (—CH₂—) is replaced with a sulfonyl group (—SO₂—), a carbonyl group ((—C(═O)), an ether group (—O—), a sulfide (—S—), a sulfoxide group (—SO—), an ester group (—C(═O)O—), an amide group (—C(═O) NR—, wherein R is hydrogen or a C1 to C10 alkyl group), or a combination thereof,
Y₁ is a single bond, a substituted or unsubstituted C1 to C30 alkylene group, a substituted or unsubstituted C2 to C30 alkenylene group, or a substituted C2 to C30 alkylene group or a substituted or unsubstituted C3 to C30 alkenylene group where at least one methylene (—CH₂—) is replaced by a sulfonyl group (—S(═O)₂—), a carbonyl group (—C(═O)—), an ether group (—O—), a sulfide group (—S—), a sulfoxide group (—S(═O)—), an ester group (—C(═O)O—), an amide group (—C(═O) NR—, wherein R is hydrogen or a C1 to C10 linear or branched alkyl group), an imine group (—NR—, wherein R is hydrogen or a C1 to C10 linear or branched alkyl group), or a combination thereof,
m is an integer of 1 or greater, for example 1 to 10,
k1 is 0 or an integer of 1 or greater, for example 1 to 10,
k2 is an integer of 1 or greater, for example 1 to 10, and
the sum of m and k2 may be an integer of greater than or equal to about 2, greater than or equal to about 3, (for example, 2, 3, 4, 5, or 6).

In an embodiment, in Chemical Formula 3, Y₁ is not a single bond, and m does not exceed the valence of Y₁, and the sum of k1 and k2 does not exceed the valence of L₁.

The polythiol compound may be represented by Chemical Formula 3-1:

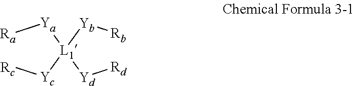

wherein, in Chemical Formula 3-1,
L₁′ is the same as L₁ of Chemical Formula 3, and may be for example, carbon, a substituted or unsubstituted C1 to C30 aliphatic hydrocarbon group (e.g., alkylene, alkenylene, alkynylene groups); a substituted or unsubstituted C6 to C30 arylene group; a substituted or unsubstituted C3 to C30 heteroarylene group; a substituted or unsubstituted C3 to C30 cycloalkylene group; or a substituted or unsubstituted C3 to C30 heterocycloalkylene groups; and,
Yₐ to Y_{d} are independently a single bond, a substituted or unsubstituted C1 to C30 alkylene group, a substituted or unsubstituted C2 to C30 alkenylene group, or a substituted or unsubstituted C2 to C30 alkylene group or a substituted or unsubstituted C3 to C30 alkenylene group where at least one methylene (—CH₂—) is replaced by a sulfonyl group (—S(═O)₂—), a carbonyl group (—C(═O)—), an ether group (—O—), a sulfide group (—S—), a sulfoxide group (—S(═O)—), an ester group (—C(═O)O—), an amide group (—C(═O)NR—) (wherein R is hydrogen or a C1 to C10 linear or branched alkyl group), an imine group (—NR—) (wherein R is hydrogen or a C1 to C10 linear or branched alkyl group), or a combination thereof, and
Rₐ to R_{d} are independently R¹ of Chemical Formula 3 or SH, provided that at least one or at least two of Rₐ to R_{d} are SH.

The center moiety, e.g., L₁ or L₁′ of Chemical Formula 3 or Chemical Formula 3-1, may include a carbon atom, a substituted or unsubstituted C1 to C30 aliphatic hydrocarbon group, a triazine moiety, a triazinetrione moiety, a quinoline moiety, a quinolone moiety, a naphthalene moiety, or a combination thereof.

The thiol compound of Chemical Formula 3 may be a polythiol compound and may include nonanedithiol, glycol dimercaptopropionate (e.g., ethylene glycol dimercaptopropionate), trimethylolpropane tris(3-mercaptopropionate) having the structure of Chemical Formula 3-2, pentaerythritol tetrakis(3-mercaptopropionate) having the structure of Chemical Formula 3-3, pentaerythritol tetrakis(2-mercaptoacetate) having the structure of Chemical Formula 3-4, tris[2-(3-mercaptopropionyloxy)alkyl] isocyanurate having the structure of Chemical Formula 3-5, a compound having the structure of Chemical Formula 3-6, a compound having the structure of Chemical Formula 3-7, a compound having the structure of Chemical Formula 3-8, or a combination thereof:

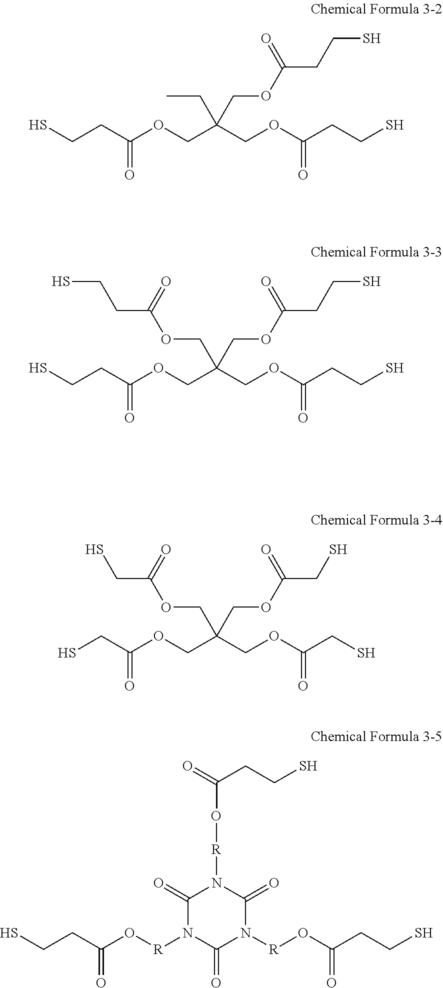

wherein, in Chemical Formula 3-5, R is a substituted or unsubstituted C1 to C10 alkylene;

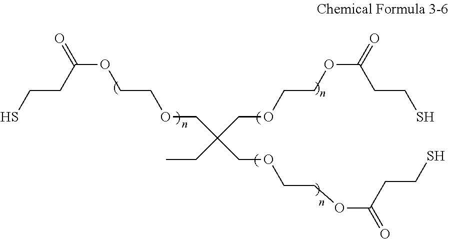

wherein, n is an integer of 1 to 20,

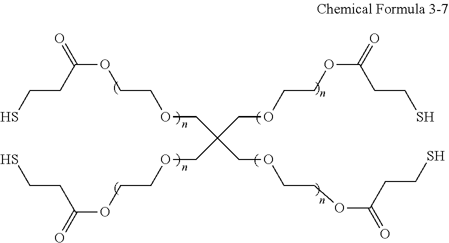

wherein, n is an integer of 1 to 20,

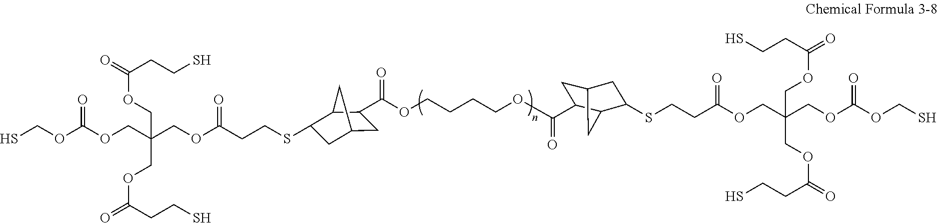

wherein, n is an integer of 1 to 20.

Without wishing to be bound by any theory, it is believed that in an embodiment, the radiation irradiated to a film containing an additive and a semiconductor nanocrystal may cause an occurrence of a photochemical reaction to change the solubility (or the dispersibility) of the irradiated portion of the film and may contribute to elimination of some surface defects of the semiconductor nanoparticle. Surprisingly the present inventors have found that in the method disclosed herein, the photocatalytic activity of the semiconductor nanoparticle can facilitate or activate the crosslinking between the ligands via the additive rather than a polymerization reaction. The semiconductor nanocrystal particle may be (or may act as) a photocatalyst for producing thiyl radicals from thiol groups, and the carbon carbon double bonds present in the ligand may participate in the thiol-ene reaction initiated by the semiconductor nanoparticle.

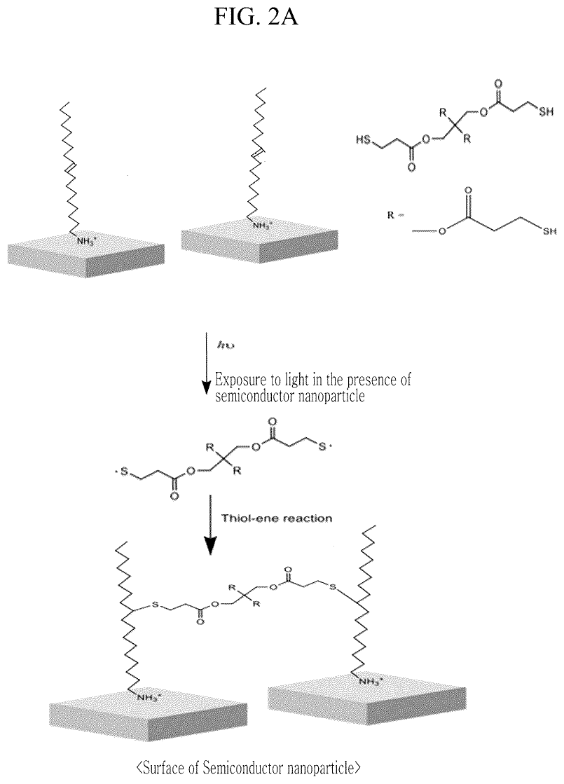

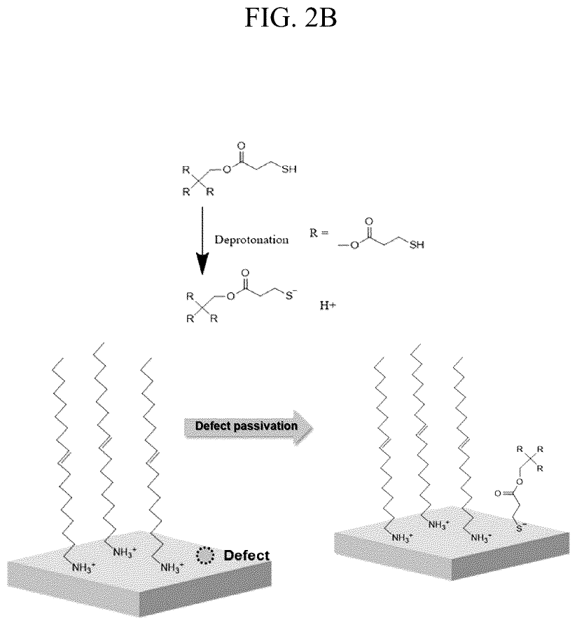

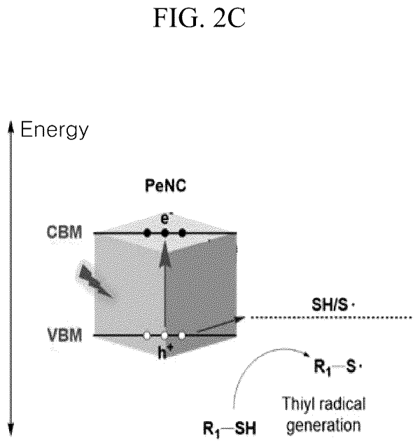

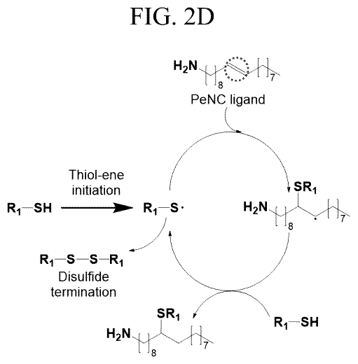

Without wishing to be bound by any theory, in the direct photocatalytic patterning according to the method disclosed herein, the reaction may be considered from the energy point of view as follows: In the method of an embodiment, the semiconductor nanocrystal particle may be exposed to photons greater than the bandgap energy thereof, an exciton may be formed, and in the case where the redox level of the additive is higher than the energy level of the valance band maximum of the semiconductor nanocrystal particle, the hole excited from the exciton may be jumping to the thiol group of the additive, thereby providing reactive thiyl radicals. (see FIG. 2C)

The redox potential of the additive or thiol compound may range from about 0.1 eV to about 10 eV, or from about 0.2 eV to about 5 eV, from about 0.3 eV to about 3 eV, from about 0.35 eV to about 2 eV, from about 0.4 eV to about 1 eV, from about 0.5 eV to about 0.7 eV, or a combination thereof.

Without wishing to be bound by any theory, when the film is irradiated with radiation in the method of an embodiment, for example, as described herein, the carbon-carbon unsaturated bond included in the organic ligand of the semiconductor nanoparticle may react with a thiol moiety of an additive (hereinafter, a thiol-ene reaction). (see FIG. 2A) The mechanism of the thiolene reaction may be shown in FIG. 2D. As shown in FIG. 2D, the formed thiyl radical may react with the ligand.

Referring to FIG. 2A, the thiol group may undergo a reaction with a carbon-carbon double bond in the presence of the energy (e.g., radiation such as light) to form a sulfur-carbon bond, and such a reaction may require a catalyst or a radical product. Surprisingly, the present inventors have found that the semiconductor nanoparticle present in the film may serve as a photocatalyst. Without wishing to be bound by a specific theory, it is believed that the (e.g., compound-based) semiconductor nanocrystal particle described herein may form an exciton when being exposed to radiation, and the exciton thus formed may act as a catalyst for the thiol-ene reaction, for example, between the carbon-carbon unsaturated bond in the ligand of the semiconductor nanoparticle and the additive, in the film. The present inventors have found that the thiol-ene reaction in the film may be performed with a relatively high reaction efficiency (even in the presence of moisture and oxygen in the film), and thus the chemical change may provide a significant difference in film properties (e.g., solubility) between a portion exposed to radiation and a portion not exposed to radiation, thereby forming a pattern with a relatively high resolution (e.g., a line width of 10 micrometers or less or 5 micrometers or less), for example via the developing process.

From a practical point of view, the patterning process may not degrade the optical properties of the semiconductor nanoparticle and may provide a relatively high-resolution pattern. The direct optical patterning of an embodiment may be based on a ligand chemistry, and thus the desorption of the ligand may often occur during the patterning process, which may have an adverse effect on the passivation of the semiconductor nanoparticle, and this may lead to a decrease in the quantum efficiency (or a photoluminescence quantum yield) of the resulting pattern. Surprisingly, the present inventors have found that the thiol moiety of the additive can serve as a defective passivation agent under the radiation exposure condition of the method of an embodiment. Accordingly, the proton may be separated from the thiol group of the additive to passivate the surface of the semiconductor nanoparticle in the form of R—S⁻ thiolate. In addition, the method may involve the use of a relatively high-stability semiconductor nanocrystal particle including a relatively strongly binding ligand.

A semiconductor nanoparticle with a relatively high stability (e.g., a perovskite semiconductor nanocrystal based nanoparticle) may be prepared by the incorporation of a zinc halide (ZnX₂, X is F, Cl, Br, I, or a combination thereof) in the synthesis step. Without wishing to be bound by theory, the zinc ion may preferentially bind to a functional group bonded to the surface of the semiconductor nanoparticle such as an oleate group. The final semiconductor nanocrystal particle synthesized in the presence of the zinc halide may include an alkylammonium halide (e.g., an alkyl ammonium bromide) with high binding affinity as a predominant ligand. Without wishing to be bound by any theory, it is believed that the strong binding of the ammonium-based ligand can increase the photoluminescence quantum yield of the semiconductor nanocrystal particles. In addition, the present inventors have found that in the case where the surface of the semiconductor nanoparticle is functionalized with an alkylammonium group, an additive containing a thiol group may be added to the nanoparticle dispersion solution to prevent or suppress a decrease in the dispersion stability, and the light emitting efficiency of the semiconductor nanoparticle may not substantially decrease, for example, even after the patterning process. The semiconductor nanoparticle of an embodiment may be a ZnX₂-treated perovskite-based semiconductor nanocrystal particle, which may be used as a photocatalyst and a patterning component.

Without wishing to be bound by any theory, in semiconductor nanocrystal particles synthesized in the presence of a zinc halide, the ligand (e.g., oleylamine, etc.) may be a ligand with a strong binding energy, and it is believed that the additive may more effectively serve as a passivation agent and thus further increase an optical property of the semiconductor nanoparticle or the film including the same. In an embodiment, the thioether moiety formed by a thiol-ene reaction induced by the radiation such as an UV light may be more efficient for passivation.

The effective surface passivation by the dual role of the additive in the method of an embodiment may also increase a photostability of the patterned film. Surprisingly, the present inventors have found that, when irradiated with a relatively high-power UV light (for example, of about 40 mW cm⁻²), the maintenance ratio of the light emitting efficiency of the patterned film according to the method of an embodiment may be relatively higher than that of the film produced without the additive. The relatively high stability of the patterned film obtained by the method of an embodiment may suggest that the method of an embodiment may be a non-destructive and efficient patterning method, and may be used in the manufacture of various photoelectronic devices.

The additive may not cause a substantial degradation of the optical property of the semiconductor nanoparticle. For example, the addition of the additive may not cause a substantial shift in the peak emission wavelength of the luminescent spectrum or the first absorption wavelength of the UV-Vis absorption spectrum of the semiconductor nanoparticle. The patterning method may not cause a substantial change in the crystal structure or the average size of the semiconductor nanoparticle (e.g., the semiconductor nanocrystal particle). The photoluminescent quantum yield (e.g., an absolute quantum yield) of the semiconductor nanocrystal particle thin film can be maintained during the patterning process and the addition of the additive described herein may result in an increase of the quantum yield (e.g., by about 5% or greater, about 7% or greater, or about 9% or greater), in comparison with the unadded film prepared without the addition of the additive.

In the patterning method, due to the possible passivation of the additive for the defect of the semiconductor nanoparticle, the ink composition described herein may exhibit an increased dispersibility compared to a semiconductor nanocrystal dispersion not including the additive. Accordingly, in the patterning method according to an embodiment, when being left under a dark condition for an extended time period (e.g., of about 10 days), the ink composition may exhibit a precipitate only in a limited amount of semiconductor nanoparticles or may not exhibit any substantial precipitation of the semiconductor nanoparticles as observed by naked eyes. In contrast, in case of the pristine solution including the semiconductor nanoparticle without the additive, the precipitation of a significant amount of semiconductor nanoparticles may be observed. The relatively high colloidal stability of the ink composition may be further advantageous for the patterning method of an embodiment.

In the method disclosed herein, the incorporation of the additive and the irradiation of radiation may not cause a substantial damage to the structure of the semiconductor nanocrystal particle and may contribute to the enhancement of the optical property of the semiconductor nanoparticle or the patterned film including the same. As measured by a time-resolved photoluminescence (TRPL) analysis, after the addition of the additive, the average lifespan of the semiconductor nanoparticle may increase (e.g., from 3.5 ns to 6.32 ns) and the non-emission recombination ratio may decrease. As measured by the TRPL analysis, the average lifespan of the semiconductor nanoparticle in the patterned film may be greater than or equal to about 3.5 ns, greater than or equal to about 3.53 ns, greater than or equal to about 6 ns, or greater than or equal to about 6.3 ns. The average lifespan of the semiconductor nanoparticle in the patterned film may be less than or equal to about 7 ns.

Without wishing to be bound by any theory, the preservation of photophysical and structural properties of the semiconductor nanoparticle may suggest the dual role of the additive (i.e., a crosslinking agent and an efficient defect passivation agent) in the method described herein.

The additive may provide a total number of the reactive functional groups suitable to provide a pattern in the composition and may exhibit a desired compatibility with the semiconductor nanoparticles. As the number of the reactive functional units increases, the crosslinking efficiency may increase, as well. The additive may exhibit a compatibility with a non-polar solvent for the semiconductor nanoparticle.

The additive may be dissolved in a non-polar solvent (e.g., toluene), and the prepared solution (e.g., from about 0.025 M to about 2.5 M) may not exhibit distinct absorbance characteristics with respect to the radiation to be exposed (e.g., with respect to a UV light having a wavelength of about 365 nm to about 405 nm, such as an I-line or a H-line), and this may suggest that the thiol group of the additive may not be converted into thiyl radical for the radiation exposure itself, and the semiconductor nanocrystals described herein may serve as an appropriate photocatalyst.

In the patterning method, the carbon-carbon unsaturated bond of the ligand of adjacent semiconductor particles in the film may participate in the thiol-ene reaction with the thiol moiety of the additive, thereby changing the solubility of the semiconductor particles with respect to a solvent (e.g., the first solvent described herein). By the change in the solubility, the film that is soluble with respect to the first solvent prior to exposure may have a dissolution resistance with respect to the first solvent after the exposure to the radiation. By the change in the solubility described herein, the semiconductor nanoparticle present in the region exposed to the radiation (e.g., present in the first region) may not be removed and remain during the developing process described herein, and accordingly, a desired patterned film of the semiconductor nanoparticles may be obtained. As used herein, the expression “being soluble with respect to a given solvent” may refer to the case where when a semiconductor nanoparticle film is in contact with the given solvent, the semiconductor nanoparticles included in the film may be dispersed in the given solvent (e.g., a first solvent) to form a colloidal dispersion state. As used herein, the colloidal dispersion state refers to the case where a size (or an average size) of a discontinuous phase (e.g., a particulate phase) in a continuous phase (e.g., a solid phase such as a polymer phase or a liquid phase such as a solvent phase) may be in a nanoscale of less than or equal to about 1 micrometer (μm), for example, less than or equal to about 900 nm, less than or equal to about 800 nm, less than or equal to about 700 nm, less than or equal to about 600 nm, less than or equal to about 500 nm, less than or equal to about 400 nm, less than or equal to about 300 nm, less than or equal to about 200 nm, less than or equal to about 150 nm, less than or equal to about 100 nm, less than or equal to about 90 nm, less than or equal to about 80 nm, less than or equal to about 60 nm, less than or equal to about 50 nm, less than or equal to about 40 nm, or less than or equal to about 30 nm. The semiconductor nanoparticles or the film including the same can have a dissolution resistance with respect to a given solvent (e.g., the first solvent) and when being in contact with the given solvent (e.g., the first solvent), the semiconductor nanoparticles (e.g., included in the film) may not or do not form a colloidal dispersion in the given solvent. For example, the semiconductor nanoparticles or the film including the same can have a dissolution resistance with respect to a given solvent and when being in contact with the given solvent (e.g., the first solvent), at least about 50%, about 60%, about 70%, about 80%, about 90%, about 95%, about 99%, or higher (e.g., substantially all of) the semiconductor nanoparticles included in the radiation treated region of the film are not removed from the film into the solvent.

In the patterning method, it is possible to effectively prevent the deterioration of a light emitting property of the semiconductor nanoparticles. The semiconductor nanoparticle included in the patterned film may exhibit a light emitting efficiency that is comparable to or higher than the original light emitting efficiency measured for the same semiconductor nanoparticle in a dispersing solvent. Without wishing to be bound by any theory, in the patterned film, the additive may be further bonded to a surface of the semiconductor nanoparticle, and this may bring forth a change in an optical property (e.g., an increase in a quantum efficiency) of the semiconductor nanoparticle. Without wishing to be bound by any theory, the additive (or the thiol group thereof) present in the film may have a S-moiety (e.g., formed via the deprotation or by the radical formation after the radiation exposure). The S-moiety may further passivate a surface defect such as a metal cation (e.g., a zinc cation, a lead cation, a cesium cation, etc.) present on a surface of an adjacent semiconductor nanoparticle (see FIG. 2B).

In the patterning method, the light emitting efficiency (e.g., the quantum efficiency) of the patterned film may be substantially the same as the quantum efficiency of the semiconductor nanoparticle prior to being included in the film (hereinafter referred to as the initial quantum efficiency), or may be greater than the initial quantum efficiency by at least about 3%, at least about 5%, or at least about 10%. In an embodiment, a relative light emitting efficiency of the patterned film with respect to the initial light emitting efficiency (about 100%) may be greater than or equal to about 70%, greater than or equal to about 75%, greater than or equal to about 80%, greater than or equal to about 85%, greater than or equal to about 90%, greater than or equal to about 100%, greater than or equal to about 101%, greater than or equal to about 103%, greater than or equal to about 105%, greater than or equal to about 107%, greater than or equal to about 110%, greater than or equal to about 115%, greater than or equal to about 120%, greater than or equal to about 130%, or greater than or equal to about 150%.

The patterned film may have a relative light emitting efficiency of greater than or equal to about 100%:

$$\\ Relative light emitting efficiency ( \% ) = A / B \times 100$$

A: quantum efficiency of the patterned film
B: quantum efficiency of the film made up of the semiconductor nanoparticles without the above additive

The relative light emitting efficiency may be greater than or equal to about 70%, greater than or equal to about 75%, greater than or equal to about 80%, greater than or equal to about 85%, greater than or equal to about 90%, greater than or equal to about 100%, greater than or equal to about 101%, greater than or equal to about 103%, greater than or equal to about 105%, greater than or equal to about 107%, greater than or equal to about 110%, greater than or equal to about 115%, greater than or equal to about 120%, greater than or equal to about 125%, greater than or equal to about 130%, or greater than or equal to about 150% and less than or equal to about 200%, less than or equal to about 180%, less than or equal to about 170%, less than or equal to about 160%, less than or equal to about 150%, less than or equal to about 140%, less than or equal to about 130%, less than or equal to about 125%, less than or equal to about 110%, less than or equal to about 106%, or less than or equal to about 104%.

The forming of a film (e.g., first film) including the additive and the semiconductor nanoparticle may include obtaining a composition (e.g., an ink, also referred to as a coating composition or an ink composition) including the additive and the semiconductor nanoparticle (refer to S1 of FIG. 1A). In an embodiment, the formation of the film may include washing of the semiconductor nanoparticle, which can be performed before the ink is prepared. Surprisingly, the present inventors have found that a more improved pattern quality may be obtained by the washing process. The washing may be carried out once or more times, for example, twice or three times. In an embodiment, the semiconductor nanoparticle may include a perovskite nanocrystal particle, and the semiconductor nanoparticles thus prepared may be washed with using an acetate-based washing solvent such as methyl acetate. Without wishing to be bound by any theory, an unreacted ligand, or a solvent may be removed during the washing process, and this may bring an improvement of the pattern quality. The washing solvent may include the non-solvent described herein. A surface state of the semiconductor nanoparticle may have an effect on the pattern formation, and after a property of the surface of the semiconductor nanoparticle may be checked first and if desired a ligand exchange may be conducted prior to the preparation of the composition.

The composition may include a first solvent. The additive and the semiconductor nanoparticle may be dispersed or dissolved in the first solvent. The first solvent may be a solvent in which the semiconductor nanoparticle may form a colloidal dispersion and the additive may be dissolved. The first solvent may be a developing solvent in a developing process described herein. The change in the solubility of the semiconductor nanoparticle included in the area exposed to radiation with respect to the first solvent may be induced by a thiol-ene crosslinking reaction assisted by the photocatalytic activity of the semiconductor nanoparticle.

The first solvent may be a polar solvent. The first solvent may be a non-polar solvent. Examples of the first solvent may include a C3 to C30 amide solvent such as dimethylformamide, a cyclic ester solvent such as gamma butyrolactone, a linear ester solvent such as ethyl acetate, a cyclic amide (e.g. lactam) solvent such as N-methyl pyrrolidone, a C2 to C30 sulfoxide-based solvent such as dimethyl sulfoxide, a C1 to C30 halogenated hydrocarbon solvent such as dichloroethylene, trichloroethylene, and chloroform, a C3 to C30 alkane solvent such as octane, hexane, and heptane, a substituted or unsubstituted C6 to C30 aromatic hydrocarbon solvent such as chlorobenzene, dichlorobenzene, styrene, toluene, and the like, an alicyclic hydrocarbon solvent such as cyclohexene and cyclohexane, or a combination thereof.

The first solvent may include toluene, octane, hexane, chlorobenzene, dichlorobenzene, chloroform, xylene, or a combination thereof. The first solvent may include dimethylformamide, gamma butyrolactone, N-methyl pyrrolidone, dimethyl sulfoxide, dichloroethylene, trichloroethylene, chloroform, chlorobenzene, dichlorobenzene, styrene, xylene, toluene, cyclohexene, or a combination thereof.

A method of preparing an ink composition is not particularly limited. In an embodiment, a semiconductor nanoparticle solution (or dispersion) including semiconductor nanoparticle in a first solvent may be prepared, and an additive may be added to the solution to prepare the composition. A concentration of the solution of the semiconductor nanoparticle may be appropriately selected. A concentration of the semiconductor nanoparticles in the semiconductor nanoparticle solution may be greater than or equal to about 0.01 mg/mL, greater than or equal to about 0.1 mg/mL, greater than or equal to about 0.5 mg/mL, greater than or equal to about 1 mg/mL, greater than or equal to about 1.5 mg/mL, greater than or equal to about 3 mg/mL, greater than or equal to about 4.5 mg/mL, greater than or equal to about 5 mg/mL, greater than or equal to about 7.5 mg/mL, greater than or equal to about 9 mg/mL, greater than or equal to about 10 mg/mL, greater than or equal to about 12 mg/mL, greater than or equal to about 14 mg/mL, greater than or equal to about 16 mg/mL, or greater than or equal to about 18 mg/mL. The concentration of the semiconductor nanoparticles in the semiconductor nanoparticle solution can be appropriately selected taking into consideration dispersibility of the semiconductor nanoparticle in the first solvent, and may be less than or equal to about 100 mg/mL, less than or equal to about 80 mg/mL, less than or equal to about 60 mg/mL, less than or equal to about 40 mg/mL, or less than or equal to about 35 mg/mL, but is not limited thereto. An amount of the additive may be, per 0.1 mg of the semiconductor nanoparticle, greater than or equal to about 0.01 μL, greater than or equal to about 0.05 μL and less than or equal to about 20 μL, less than or equal to about 10 μL, or less than or equal to about 5 μL, but is not limited thereto.

An amount of the additive in the ink composition may be appropriately selected taking into consideration an amount of the semiconductor nanoparticles, the wavelength and the dose of the radiation, a type of semiconductor nanoparticle to be used, and the line width of a pattern to be formed. In an embodiment, the amount of the additive in the ink composition may be, per a total weight of the semiconductor nanoparticle, greater than or equal to about 0.001 wt %, greater than or equal to about 0.005 wt %, greater than or equal to about 0.01 wt %, greater than or equal to about 0.05 wt %, greater than or equal to about 0.1 wt %, greater than or equal to about 0.5 wt %, greater than or equal to about 1 wt %, greater than or equal to about 3 wt %, greater than or equal to about 5 wt %, greater than or equal to about 7 wt %, greater than or equal to about 9 wt %, or greater than or equal to about 10 wt %. In an embodiment, the amount of the additive in the ink composition may be, per a total weight of the semiconductor nanoparticle, less than or equal to about 50 wt %, less than or equal to about 45 wt %, less than or equal to about 40 wt %, less than or equal to about 35 wt %, less than or equal to about 30 wt %, less than or equal to about 25 wt %, less than or equal to about 20 wt %, less than or equal to about 15 wt %, less than or equal to about 12 wt %, or less than or equal to about 8 wt %. The concentration of each component (e.g., the semiconductor nanoparticle and the thiol compound) in the ink composition can be adjusted so as to obtain a solubility change caused by irradiation that is sufficient for the development process.

In the ink composition or the film obtained therefrom (or the first region), an amount of the semiconductor nanoparticle (or an amount of the inorganic component) may be, per a total weight of the composition or a total solid content of the composition or a total weight of the film, greater than or equal to about 5 wt %, greater than or equal to about 10 wt %, greater than or equal to about 15 wt %, greater than or equal to about 20 wt %, greater than or equal to about 25 wt %, greater than or equal to about 30 wt %, greater than or equal to about 35 wt %, greater than or equal to about 40 wt %, greater than or equal to about 45 wt %, greater than or equal to about 50 wt %, greater than or equal to about 55 wt %, greater than or equal to about 60 wt %, greater than or equal to about 65 wt %, greater than or equal to about 70 wt %, greater than or equal to about 75 wt %, greater than or equal to about 80 wt %, greater than or equal to about 85 wt %, greater than or equal to about 90 wt %, greater than or equal to about 95 wt %, greater than or equal to about 98 wt %, greater than or equal to about 99 wt %, or greater than or equal to about 99.5 wt %. The amount of the semiconductor nanoparticles in the composition may affect the distance between the adjacent semiconductor nanoparticles in the film, and the amount of the semiconductor nanoparticles in the composition may be adjusted in a range that is sufficient for the formation of the patterned film.

In the ink composition or the film obtained therefrom (or the first region), an amount of the semiconductor nanoparticle (or an amount of the inorganic component) may be, per a total solid content of the composition or a total weight of the film, less than 100 wt %, less than or equal to about 99.99 wt %, less than or equal to about 97 wt %, less than or equal to about 95 wt %, less than or equal to about 93 wt %, less than or equal to about 91 wt %, less than or equal to about 88 wt %, less than or equal to about 85 wt %, less than or equal to about 83 wt %, less than or equal to about 81 wt %, less than or equal to about 78 wt %, less than or equal to about 74 wt %, less than or equal to about 71 wt %, less than or equal to about 68 wt %, or less than or equal to about 65 wt %. The balance of the film may be an organic component (e.g., an organic ligand or an organic component derived from an additive).

The ink composition or the film may further include or may not substantially include a polymerizable monomer. An amount of the polymerizable monomer in the film may be less than or equal to about 5 wt %, less than or equal to about 3 wt %, less than or equal to about 1 wt %, less than or equal to about 0.5 wt %, less than or equal to about 0.1 wt %, or less than or equal to about 0.05 wt %, based on a total weight of the film. The polymerizable monomer may be a (meth)acrylic monomer having one or more carbon-carbon double bond, for example, two, three, or four or more carbon-carbon double bonds, a (meth)acrylic oligomer containing two, three, or four or more carbon-carbon double bonds, a vinyl monomer containing two, three, or four or more carbon-carbon double bonds, or a compound selected from a combination thereof. The polymerizable monomer may be or include a di(meth)acrylate compound.

The ink composition or the film may not include an organic compound containing two or more azide groups (hereinafter referred to as an azide compound); an organic binder polymer having an acid value of greater than or equal to about 50 mg KOH per gram of polymer and being soluble in an aqueous alkali solution; a hole transporting organic compound including an oxetane group or a vinyl group and an aromatic hydrocarbon group; or a combination thereof.

The azide compound may include bispersfluorophenylazide, 3,4-diazido-1-(phenylmethyl) pyrrolidine, 1,2-diazidobenzene, 1,4-diazidobenzene, 1,5-diazidohexane, 1,1′-methylenebis(4-azidobenzene), 4,4-diazidodiphenylethane, 2,6-bis(4-azidobenzylidene)cyclohexanone, or a combination thereof. The organic binder polymer may have an acid value of greater than or equal to about 80 mg KOH per gram of polymer to less than or equal to about 200 mg KOH per gram of polymer. The hole-transporting organic compound may include N4,N4′-Bis(4-(6-((3-ethyloxetan-3-yl) methoxy) hexyl)phenyl)-N4,N4′-diphenylbiphenyl-4,4′-diamine (OTPD), N4,N4′-Bis(4-(6-((3-ethyloxetan-3-yl) methoxy) hexyloxy)phenyl)-N4,N4′-bis(4-methoxyphenyl) biphenyl-4,4′-diamine (QUPD), N, N′-(4,4′-(Cyclohexane-1,1-diyl)bis(4,1-phenylene))bis(N-(4-(6-(2-ethyloxetan-2-yloxy) hexyl)phenyl)-3,4,5-trifluoroaniline) (X-F6-TAPC), N4,N4′-Di(naphthalen-1-yl)-N4,N4′-bis(4-vinylphenyl) biphenyl-4,4′-diamine (VNPB), 9,9-Bis[4-[(4-ethenylphenyl) methoxy]phenyl]-N2,N7-di-1-naphthalenyl-N2,N7-diphenyl-9H-Fluorene-2,7-diamine (VB-FNPD), 3,5-di-9H-carbazol-9-yl-N, N-bis[4-[[6-[(3-ethyl-3-oxetanyl) methoxy]hexyl]oxy]phenyl]-benzenamine (Oxe-DCDPA), or a combination thereof.

The composition or the ink thus prepared may be applied on a substrate (e.g., on an electrode or a charge auxiliary layer) to form a film. The application manner is not particularly limited and may be selected appropriately. The application may include a spin coating, an inkjet printing, a spray coating, a dip coating, a nozzle printing, a roll-to-roll printing, or a combination thereof. In an embodiment, the application may include a spin coating. In an embodiment, the spin coating may be conducted at a rotation speed of greater than or equal to about 100 revolutions per minute (rpm), greater than or equal to about 300 rpm, greater than or equal to about 500 rpm, greater than or equal to about 700 rpm, or greater than or equal to about 900 rpm and less than or equal to about 5000 rpm, less than or equal to about 4000 rpm, less than or equal to about 3500 rpm, less than or equal to about 3000 rpm, less than or equal to about 2500 rpm, less than or equal to about 2000 rpm, less than or equal to about 1500 rpm, less than or equal to about 1000 rpm, or less than or equal to about 800 rpm.

In the film thus obtained, a portion corresponding to the first region may be exposed to radiation, and the solubility of the semiconductor nanoparticles in the first region with respect to the first solvent may be changed as described herein. Exposure to radiation may be selectively performed using a photo mask. The energy of the radiation may be selected appropriately. The radiation may be light. The peak emission wavelength of the light may be greater than or equal to about 150 nm, greater than or equal to about 200 nm, greater than or equal to about 250 nm, greater than or equal to about 300 nm, or greater than or equal to about 350 nm. The peak emission wavelength of the light may be less than or equal to about 450 nm, less than or equal to about 400 nm, less than or equal to about 390 nm, less than or equal to about 380 nm, less than or equal to about 370 nm, less than or equal to about 365 nm, or less than or equal to about 360 nm. Radiation energy can be determined taking into consideration the absorption characteristics of semiconductor nanoparticles. The dose of the radiation (e.g., light intensity dose) for the film may be greater than or equal to about 0.1 mJ/cm², greater than or equal to about 0.5 mJ/cm², greater than or equal to about 1 mJ/cm², greater than or equal to about 5 mJ/cm², greater than or equal to about 10 mJ/cm², greater than or equal to about 15 mJ/cm², greater than or equal to about 20 mJ/cm², greater than or equal to about 25 mJ/cm², greater than or equal to about 30 mJ/cm², greater than or equal to about 35 mJ/cm², greater than or equal to about 40 mJ/cm², greater than or equal to about 45 mJ/cm², greater than or equal to about 50 mJ/cm², greater than or equal to about 100 mJ/cm², greater than or equal to about 500 mJ/cm², greater than or equal to about 600 mJ/cm², or greater than or equal to about 650 mJ/cm². The dose of the radiation for the film may be less than or equal to about 5000 mJ/cm², less than or equal to about 4000 mJ/cm², less than or equal to about 3500 mJ/cm², less than or equal to about 3000 mJ/cm², less than or equal to about 2500 mJ/cm², less than or equal to about 2000 mJ/cm², less than or equal to about 1500 mJ/cm², less than or equal to about 1000 mJ/cm², less than or equal to about 900 mJ/cm², less than or equal to about 500 mJ/cm², less than or equal to about 200 mJ/cm², less than or equal to about 100 mJ/cm², less than or equal to about 48 mJ/cm², less than or equal to about 40 mJ/cm², less than or equal to about 35 mJ/cm², less than or equal to about 30 mJ/cm², or less than or equal to about 25 mJ/cm². The method of an embodiment can obtain a patterned film with an improved quality even at a relatively low dose of light.

In the method, it is thought that the patterning mechanism may include the thiol-ene reaction, and the resolution of the desired pattern may be changed by adjusting the amount of the radiation exposure. An I-line UV light source may be used, and by using a relatively low dose (e.g., of less than or equal to about 400 mJ/cm², or less than or equal to about 200 mJ/cm²), a pattern of 1 μm or less, for example, 500 nm or 450 nm or 300 nm or 200 nm or less can be obtained. In an embodiment, an I-line UV light source may be used, and by using a relatively high dose (e.g., 500 mJ/cm² or more, or 600 mJ/cm² or more) a pattern of 1 μm or more, or 1.5 μm or more can also be obtained. In an embodiment, the semiconductor nanoparticle may include a perovskite nanocrystal (particle), and a UV light of about 275 nm can be used as radiation, and in this case, a desired resolution can be realized for example even at a relatively low dose (e.g., 100 mJ/cm² or less, or 60 mJ/cm² or less).

The exposure time to radiation is not particularly limited and may be appropriately selected. The exposure time may be 1 second or more and 3 seconds or more, 5 seconds or more and 60 minutes or less, 30 minutes or less, 20 minutes or less, 10 minutes or less, 5 minutes or less, 50 seconds or less, 30 seconds or less, or 10 seconds or less.

The film including the exposed first region may be brought into contact with a developing solvent (e.g., the first solvent), whereby at least a portion of the film (e.g., an unexposed portion) may be removed to obtain a patterned film including the first region. The first solvent for preparing the composition and the solvent for development may be the same or different. The first solvent may include an organic solvent capable of dispersing the semiconductor nanoparticles. The organic solvent may be a polar solvent. The organic solvent may be a non-polar solvent. A change in solubility of the exposed film with respect to the first solvent may allow the semiconductor nanoparticles to have solubility resistance to the first solvent. Details of the first solvent is the same as described herein.

In order to form a high-resolution pattern, the additive concentration, the radiation exposure dose, and the peak emission wavelength of the radiation may be controlled. A thickness of the pattern is not particularly limited, and may be appropriately adjusted taking into consideration a final use of the patterned film. In an embodiment, a thickness of the pattern may be greater than or equal to about 1 nm, greater than or equal to about 5 nm, greater than or equal to about 10 nm, greater than or equal to about 15 nm, or greater than or equal to about 20 nm, and/or less than or equal to about 100 μm, less than or equal to about 50 μm, less than or equal to about 30 μm, less than or equal to about 20 μm, less than or equal to about 10 μm, less than or equal to about 5 μm, less than or equal to about 1 μm, less than or equal to about 900 nm, less than or equal to about 500 nm, less than or equal to about 300 nm, less than or equal to about 200 nm, less than or equal to about 150 nm, less than or equal to about 100 nm, less than or equal to about 60 nm, less than or equal to about 50 nm, less than or equal to about 30 nm, less than or equal to about 10 nm, or less than or equal to about 5 nm, or a combination thereof.

The method as described herein may provide a simple and general-purpose method for relatively precisely patterning semiconductor nanoparticles (or a film including the same) that may form a colloidal dispersion without substantial damage to their optical or structural properties. In the method, a dual role of the click chemical reagent (i.e., a compound with two or more, three or four or more thiol groups) and the semiconductor nanoparticle that acts as a photocatalyst can provide a pattern of the desired quality at a relatively low radiation amount. Surprisingly, the present inventors have found that the yield of the thiol-ene reaction can be significantly increased by the photocatalytic activity of semiconductor nanocrystal particles according to the method of one embodiment. This increase may enable crosslinking between semiconductor nanocrystal particles, resulting in a change in solubility to a degree capable of pattern formation without the need for an additional photoinitiator. The semiconductor nanocrystal particles in the obtained pattern may exhibit increased luminous efficiency.

The underlying patterning mechanism by the radiation for the photochemical conversion of the surface ligand and the additive, includes, for example, the formation of the thiol-ene reaction and the initiation of thiol-ene reactions, as described herein.

The pattern obtained according to the method as described herein may exhibit improved quality (with a high resolution feature size of less than or equal to about 1 μm and/or increased luminous efficiency). According to the method, a clean- and relatively uniform pattern may be obtained. Advantageously, a pattern having a relatively high resolution may be obtained with a relatively high uniformity. The pattern thus prepared may have a relatively low surface roughness, for example, of, less than or equal to about 500 nm, less than or equal to about 400 nm, less than or equal to about 300 nm, less than or equal to about 250 nm, or less than or equal to about 200 nm and greater than or equal to about 1 nm, greater than or equal to about 10 nm, greater than or equal to about 50 nm, or greater than or equal to about 100 nm.

The obtained patterned film (or the first region of the patterned film) may have a line with of less than or equal to about 100 μm, less than or equal to about 80 μm, less than or equal to about 50 μm, less than or equal to about 25 μm, less than or equal to about 15 μm, less than or equal to about 10 μm, less than or equal to about 8 μm, less than or equal to about 5 μm, less than or equal to about 3 μm, less than or equal to about 2 μm, or less than or equal to about 1 μm. As determined by electron microscopy analysis, the obtained patterned film may have a line edge roughness (LER) of less than or equal to about 500 nm, less than or equal to about 450 nm, less than or equal to about 400 nm, less than or equal to about 350 nm, less than or equal to about 300 nm, less than or equal to about 250 nm, less than or equal to about 220 nm, less than or equal to about 200 nm, less than or equal to about 190 nm, or a combination thereof. A method of measuring the line edge roughness is known in the art and may be based on an electron microscope analysis result (e.g., a scanning electron microscope analysis). The measurement of the line edge roughness can be easily and reproducibly conducted by using a commercially available image analysis device.

The patterned film obtained can exhibit increased stability. Surprisingly, the present inventors have found that the film of the patterned semiconductor nanocrystal particles can exhibit or maintain a similar quality (e.g., luminous efficiency) as immediately after being manufactured, for example, even when it is left for a predetermined period (e.g., 10 days or more, 50 days or more, 100 days or 150 days or more) under an ambient condition.

In XPS analysis of the obtained patterned film, the S2p spectrum may exhibit a changed peak according to a change in an additive (e.g., a thiol moiety). In an embodiment, S2p_{1/2} and S2p_{3/2}, respectively, may exhibit a peak intensity at a reduced binding energy, for example, of 164 eV or less (e.g., 163 eV or more, or 163.75 eV or less) and 163 eV or less (e.g., 162 eV or more, or 162.82 eV or less). Without wishing to be bound by any theory, it may represent a crosslinking moiety between the additive and the ligand. In the method according to an embodiment, continuous orthogonal patterning of Red, Green, Blue patterns may be realized. The method of an embodiment may provide a pattern (e.g., a patterned film) of semiconductor nanocrystal particles exhibiting an increased photoluminescent quantum efficiency (PLQY) and photostability without an additional post-treatment in such a continuous patterning. Accordingly, the patterned film obtained according to the method of an embodiment may include the first region 1 configured to emit the first light. The patterned film may further include a second region 2 configured to emit second light, a third region 3 configured to emit third light, or a combination thereof (refer to FIG. 1C). The peak emission wavelength of the first light, the peak emission wavelength of the second light, and the peak emission wavelength of the third light may be different from each other. The second region may be formed by repeating the above-described patterning process on a substrate having a patterned film including the first region. The third region may be formed by repeating the patterning method described herein on a substrate having a patterned film including the first region and the second region. A partition wall may be or may not be disposed independently between the first region and the second region, between the second region and the third region, between the third region and the first region, respectively.

The patterning method as described herein can be extended to a metal oxide nanoparticle, a carbon dot, a graphene quantum dot, a high-carrier-mobility semiconducting polymer, and even an organic small molecule as well as the patterning of semiconductor nanocrystal particles. This patterning method can contribute to non-destructive high-resolution patterning in relation to the manufacture of various electronic devices or photoelectric devices or integrated circuits thereof.

The patterned film obtained according to the method described herein may be used as a light emitting layer in various electronic devices (e.g., an electroluminescent device or a display device), or as a color conversion layer or a color conversion panel in a photoluminescent device or panel. The display panel or electronic device may include a light source (or a light emitting panel) and the patterned film, and the light source may be configured to provide light (e.g., blue light) of a predetermined wavelength to the patterned film. Type of the light source is not particularly limited, and may include an LED, an OLED, or a combination thereof. The patterns obtained according to the method of an embodiment may be used for a next-generation device such as an augmented reality headset, a stretchable display, a hyperspectral image sensor, and a smart healthcare device.

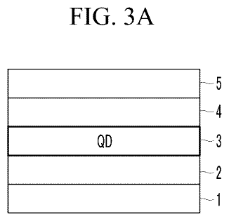

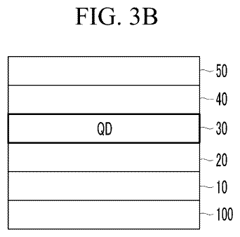

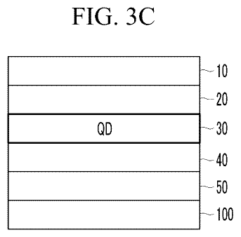

In an embodiment, an electroluminescent device includes a first electrode 1 and a second electrode 5, for example, spaced apart from each other (e.g., each having a surface opposite the other, i.e., each with a surface facing each other); a light emitting layer 3 disposed between the first electrode 1 and the second electrode 5; optionally a hole transporting layer 2 disposed between the light emitting layer 3 and the first electrode 1, and optionally an electron transport layer 4 between the light emitting layer 3 and the second electrode 5. The light emitting layer includes a pattern of a film including a first region configured to emit a first light, and the first region includes a semiconductor nanoparticle and a moiety containing a carbon-sulfur bond, and the semiconductor nanoparticle is configured to emit the first light and exhibits a dissolution resistance to a predetermined first solvent. The hole transport layer may include a hole transport material and may not include the semiconductor nanoparticle. The hole auxiliary layer may include a hole transport layer (e.g., an organic compound), a hole injection layer, or a combination thereof. (see FIGS. 3A, 3B, and 3C).

Details of the light emitting layer are the same for the patterned film including the first region described herein. Details of the first solvent are the same as described herein.

The first electrode 1 or the second electrode 5 may include an anode or a cathode. In one embodiment, the first electrode may include a cathode (or an anode), and the second electrode may include an anode (or a cathode). In one embodiment, the second electrode includes a cathode. In the electroluminescent device of an embodiment, the first electrode 10 or the second electrode 50 may be disposed on a (transparent) substrate 100. The transparent substrate may be a light extraction surface. (See FIGS. 3B and 3C). The light emitting layer may be disposed in a pixel in a display device.

In the electroluminescent device, the first electrode 10 or the second electrode 50 may be disposed on the (transparent) substrate 100. Referring to FIG. 3B and FIG. 3C, in a light emitting (e.g., electroluminescent) device of an embodiment, a light emitting layer 30 may be disposed between a first electrode (e.g., anode) 10 and a second electrode (e.g., cathode) 50. The cathode 50 may include an electron injection conductor. The anode 10 may include a hole injection conductor. The work functions of the electron/hole injection conductors included in the cathode and the anode may be appropriately adjusted and are not particularly limited. For example, the cathode may have a small work function and the anode may have a relatively large work function, or vice versa.

The electron/hole injection conductors may include a metal-based material (e.g., a metal, a metal compound, an alloy, or a combination thereof) (e.g., aluminum, magnesium, tungsten, nickel, cobalt, platinum, palladium, calcium, LiF, etc.), a metal oxide such as gallium indium oxide or indium tin oxide (ITO), or a conductive polymer (e.g., having a relatively high work function) such as polyethylene dioxythiophene, but are not limited thereto.

The first electrode, the second electrode, or a combination thereof may be a light-transmitting electrode or a transparent electrode. In an embodiment, both the first electrode and the second electrode may be a light-transmitting electrode. The electrode(s) may be patterned. The first electrode, the second electrode, or a combination thereof may be disposed on a (e.g., insulating) substrate. The substrate may be optically transparent (e.g., may have a light transmittance of greater than or equal to about 50%, greater than or equal to about 60%, greater than or equal to about 70%, greater than or equal to about 80%, greater than or equal to about 85%, or greater than or equal to about 90% and, for example, less than or equal to about 99%, or less than or equal to about 95%). The substrate may include a region for a blue pixel, a region for a red pixel, a region for a green pixel, or a combination thereof. A thin film transistor may be disposed in each region of the substrate, and one of a source electrode and a drain electrode of the thin film transistor may be electrically connected to the first electrode or the second electrode.

The light-transmitting electrode may be disposed on a (e.g., insulating) transparent substrate. The substrate may be a rigid or a flexible substrate. The substrate may include a plastic or organic material such as a polymer, an inorganic material such as a glass, or a metal.

The light-transmitting electrode may be made of, for example, a transparent conductor such as indium tin oxide (“ITO”) or indium zinc oxide (“IZO”), gallium indium tin oxide, zinc indium tin oxide, titanium nitride, polyaniline, LiF/Mg: Ag, or the like, or a metal thin film of a single layer or a plurality of layers, but is not limited thereto. If one of the first electrode and the second electrode is an opaque electrode, the opaque electrode may be made of an opaque conductor such as aluminum (Al), a lithium-aluminum (Li:Al) alloy, a magnesium-silver (Mg:Ag) alloy, or a lithium fluoride-aluminum (LIF:Al) compound.

A thickness of each of the electrodes (the first electrode, the second electrode, or each of the first electrode and the second electrode) is not particularly limited and may be appropriately selected taking into consideration device efficiency. For example, the thickness of the electrode may be greater than or equal to about 5 nm, greater than or equal to about 10 nm, greater than or equal to about 20 nm, greater than or equal to about 30 nm, greater than or equal to about 40 nm, or greater than or equal to about 50 nm. For example, the thickness of the electrode may be less than or equal to about 100 micrometers (μm), less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 1 μm, less than or equal to about 900 nm, less than or equal to about 500 nm, or less than or equal to about 100 nm.

The method of forming the electrode is not particularly limited, and may be appropriately selected depending on the material. In an embodiment, the electrode may be formed by deposition, coating, or a combination thereof, but is not limited thereto.

The light emitting layer 3, 30, QD disposed between the first electrode 1 and the second electrode 5 (e.g., the anode 10 and the cathode 50) may include a semiconductor nanoparticle (e.g., a blue light emitting nanoparticle, a red light emitting nanoparticle, a green light emitting nanoparticle, or a combination thereof). The light emitting layer may include the patterned semiconductor nanocrystal film described herein.

The first region of the patterned film of an embodiment may be disposed to correspond to a first pixel in a display device described herein, for example. The second region of the patterned film of an embodiment may be disposed to correspond to a second pixel in a display device described herein, for example. The third region of the patterned film of an embodiment may be disposed to correspond to a third pixel in a display device described herein, for example. Each of the regions may be (e.g., optically) separated from an adjacent region by a partition wall. The partition wall may include a light blocking element such as a black matrix. In an embodiment, a partition wall may be disposed between the first region(s), the second region(s), and the third region(s). In an embodiment, each of the first region(s), the second region(s), and the third region(s) may be optically isolated. (See FIG. 1C)

On the light emitting layer, for example, an electron auxiliary layer disposed between the second electrode and the light emitting layer may be included. The electron auxiliary layer may include an organic material-based electron transport layer. Types of organic materials are described herein. The electron auxiliary layer may include an electron transport layer based on zinc oxide nanoparticles. The electron transport layer may include zinc oxide nanoparticles. In an embodiment, a separate electron injection layer may be disposed between the second electrode and the electron transport layer, but is not limited thereto. The electron transport layer may be disposed adjacent to the light emitting layer (e.g., directly above the light emitting layer). In an embodiment, the electron transport layer may contact the light emitting layer.

The zinc oxide (nanoparticle) may include zinc; and, optionally, a Group IIA metal, Zr, W, Li, Ti, Y, Al, gallium, indium, tin (Sn), cobalt (Co), vanadium (V), or a combination thereof. The zinc oxide (nanoparticle) may include zinc, a Group IIA metal, and, optionally, an alkali metal.

The metal oxide may include zinc oxide, zinc magnesium oxide, or a combination thereof. The metal oxide may include Zn₁₋ₓMₓO, wherein M is Mg, Ca, Zr, W, Li, Ti, Y, Al, or a combination thereof and 0≤x≤0.5. In the formula, x may be greater than or equal to about 0.01, greater than or equal to about 0.03, greater than or equal to about 0.05, greater than or equal to about 0.07, greater than or equal to about 0.1, greater than or equal to about 0.13, greater than or equal to about 0.15, greater than or equal to about 0.17, greater than or equal to about 0.2, greater than or equal to about 0.23, or greater than or equal to about 0.25. In the formula, x may be less than or equal to about 0.47, less than or equal to about 0.45, less than or equal to about 0.43, less than or equal to about 0.4, less than or equal to about 0.37, less than or equal to about 0.35, or less than or equal to about 0.3. The metal oxide (or the zinc oxide) may further include magnesium. In an embodiment, the electron auxiliary layer (or the zinc oxide) may include Zn₁₋ₓMgₓO (wherein x is greater than 0 and less than or equal to about 0.5, x is the same as described herein), ZnO, or a combination thereof. The zinc oxide may further contain magnesium.

The zinc oxide nanoparticles may have a particle size (e.g., an average particle size) of greater than or equal to about 1 nm, greater than or equal to about 2 nm, greater than or equal to about 2.5 nm, greater than or equal to about 3 nm, or greater than or equal to about 3.5 nm and less than or equal to about 10 nm, less than or equal to about 9 nm, less than or equal to about 8 nm, less than or equal to about 7 nm, less than or equal to about 6 nm, less than or equal to about 5 nm, or less than or equal to about 4.5 nm.

In an embodiment, the zinc oxide nanoparticle may be prepared in any proper method, which is not particularly limited. The preparation of the zinc oxide nanoparticles may include a sol-gel reaction. In an embodiment, the zinc oxide (e.g., zinc magnesium oxide) nanoparticle may be prepared by placing a zinc compound (e.g., an organic zinc compound such as zinc acetate dihydrate) and optionally an additional metal compound (e.g., an additional organic metal compound such as magnesium acetate tetrahydrate) in an organic solvent (e.g., dimethylsulfoxide) in a flask to have a desired mole ratio and heating the same at a predetermined temperature (e.g., from about 40° C. to about 120° C., or from about 60° C. to about 100° C.) (e.g., in air), and adding a precipitation accelerator solution (for example, a solution of tetramethyl ammonium hydroxide pentahydrate and ethanol) at a predetermined rate with, e.g., while, stirring. The prepared zinc oxide nanoparticle (e.g., Zn₁₋ₓMgₓO nanoparticle) may be recovered from a reaction solution for example via centrifugation.

In an embodiment, the electron auxiliary layer or the electron transport layer may be prepared in a solution process. In an embodiment, the electron auxiliary layer or the electron transport layer may be prepared by dispersing a plurality of metal oxide nanoparticles in an organic solvent (for example, a polar solvent, a non-polar solvent, or a combination thereof) to obtain an electron transport layer precursor dispersion, which is then applied to a surface to form a film. The electron transport layer precursor dispersion may be applied to the light emitting layer or the first layer. The solution process may further include removing the organic solvent from the formed film for example by evaporation. The organic solvent may include a C1 to C10 alcohol solvent or a combination thereof.

In an embodiment, the electron auxiliary layer 4 or 40 may further include an electron injection layer, a hole blocking layer, or a combination thereof. An electron injection layer, a hole blocking layer, or a combination thereof may be disposed between the electron transport layer and the second electrode. In an embodiment, a hole blocking layer may be disposed between the light emitting layer and the electron transport layer. The thickness of the electron injection layer, the hole blocking layer, or a combination thereof is not particularly limited and may be appropriately selected. The thickness of the electron injection layer, the hole blocking layer, or a combination thereof may be greater than or equal to about 5 nm, greater than or equal to about 6 nm, greater than or equal to about 7 nm, greater than or equal to about 8 nm, greater than or equal to about 9 nm, greater than or equal to about 10 nm, greater than or equal to about 11 nm, greater than or equal to about 12 nm, greater than or equal to about 13 nm, greater than or equal to about 14 nm, greater than or equal to about 15 nm, greater than or equal to about 16 nm, greater than or equal to about 17 nm, greater than or equal to about 18 nm, greater than or equal to about 19 nm, or greater than or equal to about 20 nm, and less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 30 nm, or less than or equal to about 25 nm.

In an embodiment, a material for the electron transport layer, the electron injection layer, the hole blocking layer, or a combination thereof may include 1,4,5,8-naphthalene-tetracarboxylic dianhydride (“NTCDA”), bathocuproine (“BCP”), tris[3-(3-pyridyl)-mesityl]borane (“3TPYMB”), LiF, tris(8-hydroxyquinolinato)aluminum (“Alq₃”), tris(8-hydroxyquinolinato) gallium (“Gaq₃”), tris(8-hydroxyquinolinato) indium (“Inq₃”), bis-(8-hydroxyquinolinato) zinc (“Znq₂”), bis[2-(2-hydroxyphenyl)benzothiazolato]zinc (“Zn(BTZ)₂”), bis(10-hydroxybenzo[H]quinolinato) beryllium (“BeBq₂”), 8-(4-(4,6-di(naphthalen-2-yl)-1,3,5-triazin-2-yl)phenyl) quinolone (“ET204”), 8-hydroxyquinolinato lithium ((“Liq”), 2,2′,2″-(1,3,5-Benzenetriyl)-tris(1-phenyl-1-H-benzimidazole) (“TPBi”), an n-type metal oxide (e.g., ZnO, HfO₂, etc.), 8-(4-(4,6-di(naphthalen-2-yl)-1,3,5-triazin-2-yl)phenyl) quinolone: 8-hydroxyquinolinato lithium (“ET204: Liq”), or a combination thereof, but is not limited thereto.

In an embodiment, the electroluminescent device may further include a hole auxiliary layer. The hole auxiliary layer 2, 20 may be disposed between the first electrode 1, 10 and the light emitting layer 3, 30. The hole auxiliary layer 2, 20 may include a hole injection layer, a hole transport layer, an electron blocking layer, or a combination thereof. The hole auxiliary layer 2, 20 may be a single layer or a multilayer structure in which adjacent layers include different components. The hole auxiliary layer 2, 20 may be a single component layer or a multilayer structure in which adjacent layers include different components. The hole transport layer may include a hole transport material and may not include semiconductor nanoparticles.

The hole auxiliary layer 2, 20 may have a HOMO energy level that can be matched with the HOMO energy level of the light emitting layer 3 or the quantum dot layer 30 in order to enhance mobility of holes transferred from the hole auxiliary layer 2, 20 to the light emitting layer 3 or the quantum dot layer 30. In an embodiment, the hole auxiliary layer 2, 20 may include a hole injection layer close to, e.g., adjacent, the first electrode 1, 10 and a hole transport layer close to, e.g., adjacent, the light emitting layer 3 or the quantum dot layer 30.

In an embodiment, the material included in the hole auxiliary layer 2, 20 (e.g., a hole transport layer, a hole injection layer, or an electron blocking layer) is not particularly limited, and may include, for example, poly(9,9-dioctyl-fluorene-co-N-(4)-butylphenyl)-diphenylamine) (“TFB”), polyarylamine, poly(N-vinylcarbazole), poly(3,4-ethylenedioxythiophene) (“PEDOT”), poly(3,4-ethylenedioxythiophene): polystyrene sulfonate (“PEDOT: PSS”), polyaniline, polypyrrole, N, N, N′,N′-tetrakis(4-methoxyphenyl)-benzidine (“TPD”), 4,4′-bis[N-(1-naphthyl)-N-phenyl-amino]biphenyl (“α-NPD”), m-MTDATA (4,4′,4″-Tris[phenyl(m-tolyl) amino]triphenylamine), 4,4′,4″-tris(N-carbazolyl)-triphenylamine (“TCTA”), 1,1-bis[(di-4-toylamino)phenyl]cyclohexane (“TAPC”), a p-type metal oxide (e.g., NiO, WO₃, MoO₃, etc.), a carbon-based material such as graphene oxide, or a combination thereof, but is not limited thereto.

In the hole auxiliary layer, the thickness of each layer may be appropriately selected. For example, the thickness of each layer may be greater than or equal to about 5 nm, greater than or equal to about 10 nm, greater than or equal to about 15 nm, or greater than or equal to about 20 nm and less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, less than or equal to about 35 nm, or less than or equal to about 30 nm, but is not limited thereto.

The manufacturing of an electroluminescent device according to an embodiment may include forming a hole auxiliary layer (e.g., by vapor deposition or coating) on a first electrode or a substrate on which the first electrode is formed, and forming a light emitting layer on the substrate or the hole auxiliary layer. Forming the light emitting layer is as described above. An electron auxiliary layer is formed on the light emitting layer according to selection, and a second electrode is formed thereon to manufacture an electroluminescent device. The method of forming the electrode and the hole auxiliary layer is not particularly limited, and may be selected (e.g., formed by vapor deposition or coating) depending on the electrode or the hole auxiliary layer material.

An embodiment relates to a patterned semiconductor nanocrystal film or an electronic device including an electroluminescent device including the same. An embodiment relates to a patterned semiconductor nanocrystal film or a display device including an electroluminescent device including the same.

The display device or an electronic device may include (or may be) a handheld terminal, a monitor, a notebook computer, a television, an electronic display board, a camera, or a part for, e.g., of, an automatic, e.g., autonomous, vehicle.

Hereinafter, an embodiment is illustrated in more detail with reference to examples. However, these examples are exemplary, and the present scope is not limited thereto.

### EXAMPLES

### Analysis Method

### 1. Photoluminescence Analysis

The relative photoluminescence quantum yield (PLQY) and photoluminescence (PL) emission spectra of various emissive nanomaterial films and solutions were measured through an integrating sphere and a spectrofluorometer (JASCO FP-8550). For the PL emission spectra measurement, the solution was placed into a quartz cuvette and measured. To measure the PLQY of a solution, a mother solvent such as toluene is placed in a PLQY quartz cuvette (2 mm liquid cell 2×10 mm path length, 400 μL sample volume) and the baseline is recorded. Next, emissive nanomaterials dispersed in the mother solvent is placed to the same cuvette, and the PL emission spectrum is measured again. From these two measurement data, the spectrofluorometer peak integration value of solvent (I_{origin}), spectrofluorometer peak integration of sample (Iₛₐₘₚₗₑ), and PL emission peak integration value of sample (Iₑₘᵢₛₛᵢₒₙ) can be calculated. The excitation wavelength of PL measurement was 360 nm, and the emission wavelength range of measurement was 300 to 800 nm. The relative PLQY is then calculated by the following equation:

$$\\ Relative PLQY = {I}_{emission} / ( {I}_{origin} - {I}_{sample} ) \times 100 \% .$$

### 2. Optical and Scanning Microscopy Analysis

An optical microscope (Olympus BS51M) or a scanning microscope was used to obtain an optical micrograph of the manufactured pattern.

### 3. XPS Analysis

X-ray photoelectron spectroscopy (XPS) spectra were measured in the nitrogen atmosphere by using a Sigma Probe (Thermo VG Scientific) with an Al (1486.7 eV) source. All data were calibrated by C1s peak to 284.8 eV.

### 4. Raman Spectroscopy Analysis

Raman measurements were performed on a LabRAM HR Evolution Visible_NIR (HORIBA), 3000-200 cm⁻¹, resolution 2 cm⁻¹. Measurements were conducted by using a 1064 nm infrared (IR) laser.

### 5. TRPL Analysis

Time-resolved photoluminescence (TrPL) measurements of PeNC films were performed on a Fluorolog-QM (HORIBA).

### Synthesis Example 1-1

0.5 g of Cs₂CO₃, 1.6 mL of oleic acid (OA) and 14 mL of 1-octadecene (ODE) were mixed in a three-necked round-bottom flask and degassed at 60° C. for 1 hour. After degassing, the temperature of the mixture was increased to 120° C. to make a clear Cs-oleate solution. Then, the Cs-oleate solution was kept in a nitrogen atmosphere.

In a three-necked round-bottom flask, 700 mg of PbBr₂, 1400 mg of ZnBr₂, 6 mL of OA, 7 mL of oleyl amine (OLA), and 40 mL of ODE were mixed to form a lead bromide PbBr₂ solution. The lead bromide PbBr₂ solution was degassed at 120° C. for 1 hour. Then, the lead bromide PbBr₂ solution was kept in a nitrogen atmosphere, and its temperature was increased to 180° C. When the temperature of the PbBr₂ solution was reached at 180° C. (i.e., reaction temperature), quickly injected 3 mL of the Cs-oleate solution. After about 30 seconds to 1 min of reaction time, the reaction mixture was cooled down to room temperature, and a non-solvent (e.g., acetone) was injected to facilitate the precipitation of nanoparticles. The reaction mixture was then centrifuged to obtain cesium lead bromide (CsPbBr₃) semiconductor nanoparticles. It was confirmed that the manufactured semiconductor nanoparticles emitted green light having an emission peak wavelength of about 510 nm.

### Synthesis Example 1-2

Cesium lead bromide (CsPbBr₃)-based semiconductor nanoparticles were prepared in the same manner as in Synthesis Example 1-1, except that the temperature of the PbBr₂ solution was increased to 80° C. It was confirmed that the prepared semiconductor nanoparticles emit blue light.

### Synthesis Example 2

Cadmium oxide (CdO), octadecylphosphonic acid, and trioctylamine were put into a reactor and heated with stirring at 150° C. under vacuum. After flowing N2 into the reactor, the temperature was raised to 300° C. to form a cadmium (Cd) solution. Selenium powder and trioctylphosphine (TOP) were reacted to form a Se-TOP, which is then quickly injected into the Cd solution at 300° C. and reacted to prepare a CdSe core. The prepared core was dispersed in toluene. Zinc acetate, oleic acid, and trioctylamine were placed in a reaction flask and vacuum treated at 150° C. After flowing N₂ into the reaction flask the temperature was raised to 300° C. Sulfur powder and trioctylphosphine (TOP) were reacted to obtain S-TOP. The toluene dispersion of the prepared CdSe core and the S-TOP were then injected into the reaction flask, and the reaction proceeded. A non-solvent (ethanol) was added to facilitate the precipitation of nanoparticles, and the precipitate obtained was subject to centrifugation to provide a CdSe/ZnS semiconductor nanoparticle. It was confirmed that the prepared semiconductor nanoparticle emits blue light (peak emission wavelength: 470 nm).

### Synthesis Example 3

Indium acetate, palmitic acid, and 1-octadecene were put into a reactor and heated to 120° C. under vacuum. After one hour, the atmosphere in the reactor is converted to nitrogen. After being heated to 280° C., a mixed solution of tris(trimethylsilyl) phosphine (TMS₃P) and trioctylphosphine was quickly injected into the reactor and reacted for 20 minutes. The reaction solution was rapidly cooled to room temperature, and acetone was added thereto to facilitate the precipitation of nanoparticles, and the precipitate thus obtained was centrifuged to provide an InP semiconductor nanocrystal. The InP semiconductor nanocrystal was dispersed in toluene.

Zinc acetate, oleic acid, and trioctylamine were put in a reaction flask and vacuum-treated at 120° C. for 10 minutes. After replacing the inside of the reaction flask with N2, the temperature was raised to 220° C. The toluene dispersion of the InP semiconductor nanocrystals prepared above and the S/TOP were put into the reaction flask, and the temperature was raised to 280° C., and the reaction was conducted for 30 minutes. After completion of the reaction, the reaction solution was quickly cooled to room temperature, a non-solvent (ethanol) was added to facilitate the precipitation of the reaction product, and centrifugation was performed to obtain an InP/ZnS semiconductor nanoparticle.

The manufactured semiconductor nanoparticle emitted red light (peak emission wavelength: 620 nm).

### Example 1: Patterning Method

The cesium lead bromide semiconductor nanoparticle prepared in Synthesis Example 1 was washed three times with an acetate solvent (e.g., methyl acetate), and then dispersed in toluene to obtain a 20 to 30 mg/mL dispersion of semiconductor nanoparticle (hereinafter, PeNC). As a thiol compound, pentaerythritol tetrakis(3-mercaptopropionate) (hereinafter PTMP) was dissolved in toluene to obtain a 0.025 M additive solution.

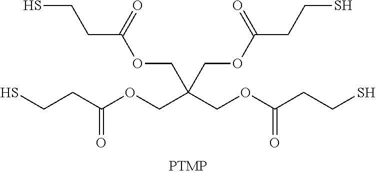 [SMILES: O=C(CCS)OCC(COC(=O)CCS)(COC(=O)CCS)COC(=O)CCS]

As a pattern formation composition, a clear patternable ink was obtained by mixing a 0.025 M additive solution and a semiconductor nanoparticle dispersion with an amount of 10 wt % of the semiconductor nanoparticle and filtering a resulting mixture with a filter.

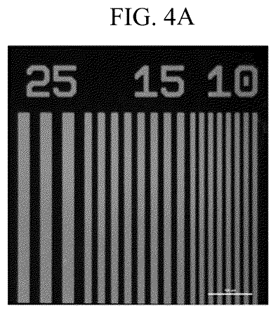

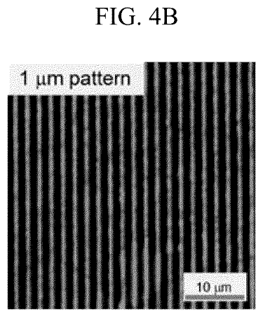

The obtained film-forming composition (patternable ink) was spin-coated on a glass or a silicon substrate at a speed of 500 to 2000 rpm for approximately 30 seconds to manufacture a film. The manufactured film was irradiated with a UV lamp (a wavelength: 365 nm, a power density 41 mW/cm²) under a photomask for about 10 seconds or less, and then the unexposed portion was removed by contacting toluene to obtain a patterned film including the first region. Optical micrographs of the obtained patterned film are shown in FIGS. 4A and 4B. From the results of FIGS. 4A and 4B, it was confirmed that a pattern having a line width of 10 micrometers or less may be obtained.

Without wishing to be bound by any theory, it is believed that rather than forming disulfide bonds, the thiol-ene reaction between the alkenyl group in the ligand and the thiol group in the additive was a dominant pattern forming mechanism for a photocatalytic patterning according to an embodiment.

### Evaluation Examples 1 to 3

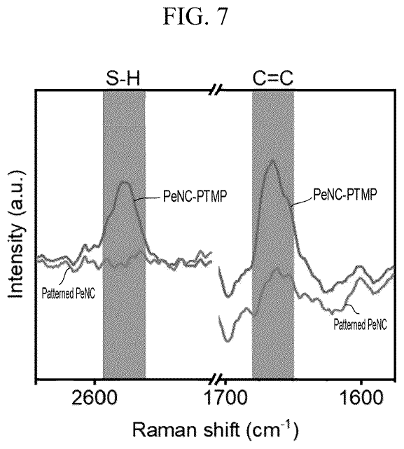

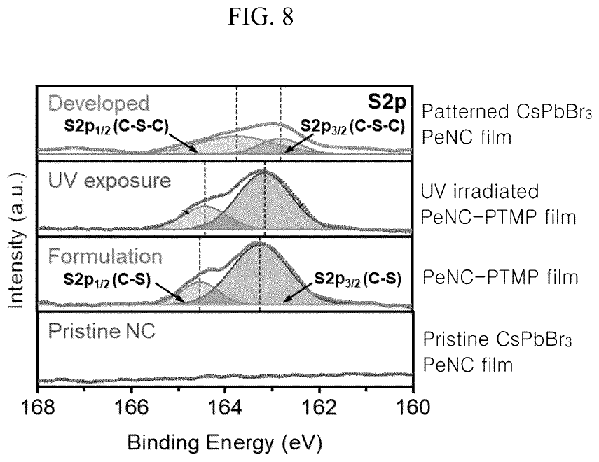

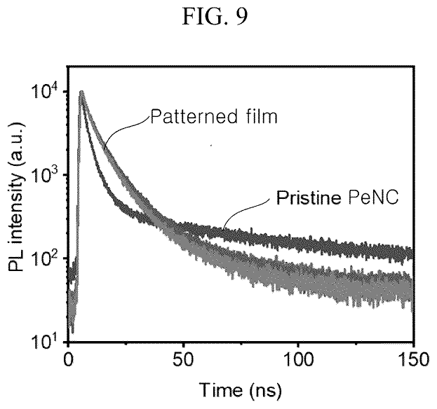

Raman spectrum analysis and XPS analysis were performed on the dispersion of the semiconductor nanoparticle obtained in Example 1 and the film during the pattern formation process, and the results thereof were shown in FIGS. 7 and 8, respectively. A TRPL analysis was performed on the dispersion of the semiconductor nanoparticles obtained in Example 1 and the film during the pattern formation process, and the results thereof are shown in FIG. 9.

FIG. 7 shows Raman spectra of PeNC-PTMP thin film, CsPbBr₃ PeNC film patterned by direct photocatalytic patterning (Patterned PeNC), and FIG. 8 is XPS S2p spectra of pristine CsPbBr₃ PeNC film (Pristine NC), PeNC-PTMP film (Formulation), UV irradiated PeNC-PTMP film (UV exposure) and patterned CsPbBr₃ PeNC film by direct photocatalytic patterning method (Developed).

In Raman spectra, the presence of PeNCs is indicated by the strong band at 1664 cm⁻¹ (stretching of alkene group (C═C) in oleylammonium ligands), whereas the presence of PTMP is indicated by a band at 2574 cm 1 (stretching mode of thiol group S—H) and another at 1737 cm⁻¹ (stretching mode of a carbonyl group (C═O)). After UV irradiation and development, the intensity of thiol and alkene stretching modes decreased significantly; this change confirms that the thiol-ene reaction has proceeded. The decreased intensities of thiol and carbonyl stretching modes during development imply that almost all unreacted PTMP molecules were removed due to their high solubility in toluene. The weak carbonyl stretching mode remaining after development was ascribed to the residual PTMP molecules acting as a crosslinker.

The XPS S2p spectra determined the change in the form of the thiol group of PTMP. The S2p spectrum showed no signal in the pristine PeNC thin film, but appeared in a PeNC-PTMP mixture thin film due to the PTMP. After deconvolution of each S2p peak, PeNC-PTMP mixture exhibited peaks at 164.53 and 163.25 eV (S2p_{1/2} and S2p_{3/2}), indicating the presence of PTMP. Upon UV exposure, the thiol-ene reaction resulted in the formation of C—S—C bonds, leading to the peak shift to lower binding energies (164.42 and 163.15 eV, for S2p_{1/2} and S2p_{3/2}, respectively). During the development process, unreacted PTMP was removed, resulting in a reduction in the intensity of the S2p peak. Therefore, only the PTMP involved in crosslinking remained, the binding energy decreased (163.75 and 162.82 eV, for S2p_{1/2} and S2p_{3/2}, respectively). These results provide evidence that PTMP was retained as the crosslinker in patterned film.

According to the TRPL results, the average life (tau average) is shown in Table 1 below.

TABLE 1

| classification | Tau average |
|---|---|
| Pristine PeNC | 3.53 ns |
| patterned | 6.26 ns |

As can be seen from Table 1, the pattern can have a significantly increased average lifetime compared to the nanoparticles without the additive. These results suggest that UV light irradiation does not damage the structure of the nanoparticles in the presence of additives and can instead contribute to the maintenance of optical properties.

### Example 2

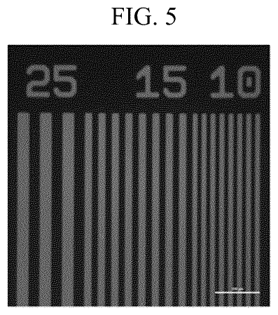

A patterned film including the semiconductor nanoparticle was prepared according to the same method as Example 1 except for using the CdSe/ZnS blue light emitting semiconductor nanoparticle prepared in Synthesis Example 2 as the light emitting material. An optical micrograph image of the prepared film pattern was shown in FIG. 5. From the results of FIG. 5, it was confirmed that a pattern having a line width of 10 micrometers or less may be obtained.

### Example 3

A patterned film including the semiconductor nanoparticle was prepared according to the same method as Example 1 except for using the InP/ZnS Red light emitting semiconductor nanoparticle prepared in Synthesis Example 3 as the light emitting material. By an optical microscopy analysis, it was confirmed that a pattern having a line width of 10 micrometers or less can be obtained.

### Evaluation Example 4

[1] In Example 1, a PLQY was measured for each of the films obtained from a cesium lead bromide toluene dispersion (pristine), the formulation obtained from the composition for pattern formation, the post-exposure film (an UV-exposure), and the developed film after development, and the relative PLQY is summarized in Table 2 below.

TABLE 2

| classification | Relative PLQY (%) |
|---|---|
| pristine | 100 |
| formulation | 106.9 |
| UV-exposure | 108.8 |
| developed | 105.1 |

From the table above, it is confirmed that the pattern obtained by the method of an embodiment may exhibit increased PLQY compared to PLQY in the semiconductor nanoparticle film state.

[2] In Example 3, a film obtained from a toluene dispersion solution of InP/ZnS nanocrystal particles, a film formulation obtained from a pattern forming composition, a film after exposure (UV-exposure), and a developed film after development are measured for PLQY, and the relative PLQY are summarized in Table 3 below.

TABLE 3

| Classification | Relative PLQY (%) |
|---|---|
| pristine | 100 |
| formulation | 116.6 |
| UV-exposure | 117.1 |
| developed | 115.1 |

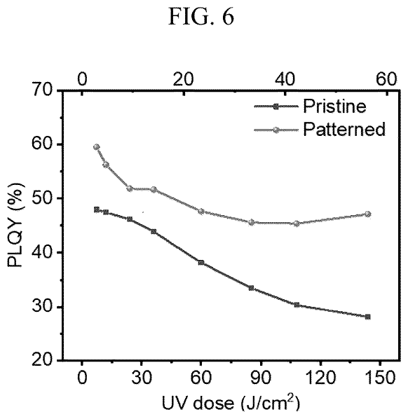

From Table 3, it is confirmed that the pattern obtained by the method of an embodiment may exhibit increased PLQY compared to PLQY in the semiconductor nanoparticle film state.

[2] In Example 1, photostability was measured for a film (pristine NC) obtained from a cesium lead bromide toluene dispersion and a film pattern obtained from a composition for pattern formation, and the result was shown in FIG. 6. Measurement of photostability was monitored for changes in PLQY while UV light having a high power wavelength of 365 nm was irradiated to the specimen.

From FIG. 6, it is confirmed that the film obtained by the method of an embodiment may exhibit improved photostability.

### Example 4

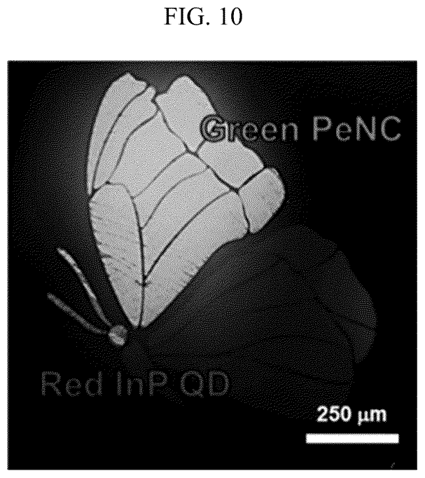

A patterned film of green light-emitting PeNC is obtained in substantially the same manner as in Example 1 (ink composition production-film formation-exposure-development). A patterned film of red light-emitting InP/ZnS is provided to a non-patterned portion of the patterned film of the obtained PeNC particles in substantially the same manner as in Example 3. The results are shown in FIG. 10.

FIG. 10 shows the result of orthogonal patterning of green light-emitting PeNC and red light-emitting InP/ZnS particles. From the result of FIG. 10, it is confirmed that a pattern of improved quality is provided without damaging adjacent patterns by continuous patterning.

### Example 5

A patterned QD-LED device having the following structure was manufactured:
indium tin oxide (145 nm)/poly(3,4-ethylenedioxythiophene): poly(styrenesulfonate) (40 nm)/poly[(9,9-dioctylfluorenyl-2,7-diyl)-co-(4,4′-(N-(4-sec-butylphenyl)diphenylamine)]/a PeNC patterned light emitting layer (30 nm)/2,2′,2″-(1,3,5-Benzinetriyl)-tris(1-phenyl-1-H-benzimidazole) (50 nm)/LiF (1 nm)/Al (100 nm).

The PeNC patterned light emitting layer was patterned in the same manner as in Example 1 using a toluene dispersion of pristine PeNC and an additive. It was confirmed that the patterned device exhibited electroluminescence, which may suggest that the charge transport properties of the pattern may be substantially the same as the pristine PeNC film.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A method of producing a patterned film having a first region configured to emit a first light, the method comprising:
forming a first film comprising a semiconductor nanoparticle and an additive, wherein the additive includes a polythiol compound containing at least two thiol groups, and the semiconductor nanoparticle is configured to emit the first light, the semiconductor nanoparticle comprises an organic ligand, and the organic ligand comprises a first functional group bonded to a surface of the semiconductor nanoparticle and a carbon-carbon unsaturated bond;
exposing a portion of the first film corresponding to the first region to a radiation to cause a change in a solubility of the semiconductor nanoparticle in an exposed area with respect to a first solvent to form a radiation treated film; and
contacting the radiation treated film with the first solvent to remove at least a portion of an unexposed area of the radiation treated film to obtain a patterned film having the first region.

2. The method of claim 1, wherein the semiconductor nanoparticle is a photocatalyst for a reaction between the organic ligand and the polythiol compound.

3. The method of claim 1, wherein the polythiol compound comprises a dithiol compound, a trithiol compound, a tetrathiol compound, or a combination thereof.

4. The method of claim 1, wherein the polythiol compound has a molecular weight of from about 50 g/mol to about 5,000,000 g/mol, and
optionally wherein the polythiol compound further comprises —O—, —CO—, —COO—, —NR—, —CONR—, a substituted or unsubstituted C1 to C20 alkylene group, a substituted or unsubstituted C2 to C20 alkenylene group, a substituted or unsubstituted C2 to C20 alkynylene group, or a combination thereof, and wherein R in —NR— and —CONR— is independently hydrogen or a C1 to C10 hydrocarbon group.

5. The method of claim 1, wherein the semiconductor nanoparticle comprises a Group II-VI compound, a Group III-V compound, a Group IV-VI compound, a Group IV element or a compound thereof, a Group II-III-VI compound, a Group I-III-VI compound, a Group I-II-IV-VI compound, a metal halide perovskite compound, a transition metal chalcogenide perovskite compound, or a combination thereof, and
wherein the first light has a red light spectrum, a green light spectrum, or a blue light spectrum, and optionally wherein a full width at half maximum of the first light is greater than or equal to about 1 nanometer and less than or equal to about 55 nanometers.

6. The method of claim 1, wherein the first functional group comprises a carboxyl group, a thiol group, an amine group, a phosphine group, a phosphine oxide group, an ester group, a hydroxyl group, or a combination thereof, and
wherein the carbon-carbon unsaturated bond comprises a carbon-carbon double bond.

7. The method of claim 1, wherein the organic ligand comprises a C1 to C50 aliphatic moiety.

8. The method of claim 1, wherein in the first film, an amount of the semiconductor nanoparticle is greater than or equal to about 60 wt % to less than or equal to about 99.99 wt %, based on a total weight of the first film, and
an amount of the additive is greater than or equal to about 0.01 wt % to less than or equal to about 40 wt %, based on a total weight of the first film.

9. The method of claim 1, wherein in the first film, an amount of a polymerizable monomer is less than about 10 wt %, based on the total weight of the first film, and the polymerizable monomer is a (meth)acrylic monomer including two or more carbon-carbon double bonds, a (meth)acrylic oligomer including a carbon-carbon double bond, a vinyl monomer, or a combination thereof.

10. The method of claim 9, wherein in the first film, an amount of the polymerizable monomer is less than about 1 wt %, based on the total weight of the first film.

11. The method of claim 1, wherein the first film does not comprise an organic compound containing two or more azide groups; an organic polymer with an acid value of greater than or equal to about 50 mg KOH per gram of the organic polymer and soluble in an aqueous alkali solution; an organic compound containing an oxetane group and an aromatic hydrocarbon group; or a combination thereof.

12. The method of claim 1, wherein the radiation is a light with a peak emission wavelength of greater than or equal to about 150 nm and less than or equal to about 450 nm, and
wherein a dose of the radiation is greater than or equal to about 0.1 mJ/cm² and less than or equal to about 5000 mJ/cm².

13. The method of claim 1, wherein the first solvent comprises an organic solvent being capable of dispersing the semiconductor nanoparticle and the organic solvent disperses the semiconductor nanoparticle in the unexposed area of the radiation treated film.

14. The method of claim 1, wherein the patterned film has a relative light emitting efficiency of greater than or equal to about 100% and less than or equal to about 200% defined by the following equation:
Relative Light emitting Efficiency (%)=A/B×100
wherein A is a quantum efficiency of the patterned film, and
B is a quantum efficiency of a film comprising the semiconductor nanoparticle without the additive.

15. An electroluminescent device comprising:
a first electrode and a second electrode, and
a light emitting layer between the first electrode and the second electrode, and a hole transport layer between the light emitting layer and the first electrode,
wherein the light emitting layer comprises a patterned film including a first region configured to emit a first light, wherein the first region is disposed corresponding to a first pixel of the electroluminescent device,
wherein the first region of the patterned film comprises a semiconductor nanoparticle and a carbon-sulfur bond containing moiety,
wherein the semiconductor nanoparticle is configured to emit the first light and exhibits a dissolution resistance to a first solvent,
wherein the first solvent comprises toluene, octane, hexane, chlorobenzene, dichlorobenzene, chloroform, xylene, or a combination thereof, and
wherein the hole transport layer comprises a hole transport material and does not include the semiconductor nanoparticle.

16. The electroluminescent device of claim 15, wherein the carbon-sulfur bond containing moiety connects two or more semiconductor nanoparticles,
wherein the semiconductor nanoparticle comprises a Group II-VI compound, a Group III-V compound, a Group IV-VI compound, a Group IV element or a compound thereof, a Group II-III-VI compound, a Group I-III-VI compound, a Group I-II-IV-VI compound, a metal halide perovskite compound, a transition metal chalcogenide perovskite compound, or a combination thereof, and
wherein the first light has a red light spectrum, a green light spectrum, or a blue light spectrum.

17. The electroluminescent device of claim 15, wherein the light emitting layer has a carbon content of greater than or equal to about 1 wt % and less than or equal to about 50 wt %, based on a total weight of the light emitting layer.

18. The electroluminescent device of claim 15, wherein the light emitting layer does not comprise a chemical species formed by a reaction between an azide group and an alkyl group; an organic polymer with an acid value of greater than or equal to about 50 mg KOH per gram of the organic polymer and soluble in an aqueous alkali solution; or a combination thereof.

19. The electroluminescent device of claim 15, wherein the electroluminescent device further comprises an electron transport layer between the light emitting layer and the second electrode, and the electron transport layer comprises zinc oxide nanoparticles.

20. A display device comprising the electroluminescent device of claim 15.
